(19) United States
(12) Patent Application Publication
(10) Pub. No.: US 2022/0199668 A1
(43) Pub. Date: Jun. 23, 2022

(54) SOLID-STATE IMAGING DEVICE

(71) Applicant: SONY SEMICONDUCTOR SOLUTIONS CORPORATION, KANAGAWA (JP)

(72) Inventors: NATSUKO OOTANI, KANAGAWA (JP); MIKINORI ITO, KANAGAWA (JP); TAKASHI TANAKA, KANAGAWA (JP); MASUMI ABE, KANAGAWA (JP); SHOHEI SHIMADA, KANAGAWA (JP)

(21) Appl. No.: 17/594,038

(22) PCT Filed: Mar. 27, 2020
(86) PCT No.: PCT/JP2020/014170

§ 371 Date: Sep. 30, 2021

(30) Foreign Application Priority Data
Apr. 12, 2019 (JP) 2019-076306

(51) Int. Cl. H01L 27/146

(52) U.S. Cl. CPC H01L 27/14621; H01L 27/1463; H01L 27/14649; H01L 27/1464

(57) ABSTRACT

The present technology relates to a solid-state imaging device capable of increasing sensitivity while reducing color mixing degradation. A solid-state imaging device includes: a substrate; a plurality of photoelectric conversion regions formed in the substrate; a trench that is formed between the photoelectric conversion regions, and penetrates the substrate; and a recessed region that includes a plurality of concave portions, and is provided above the photoelectric conversion regions and on the side of the light receiving surface of the substrate, in which the substrate includes a III-V semiconductor or polycrystalline SiXGe (1-x) (x=0 to 1). The recessed region is also provided below the photoelectric conversion regions and on the side of a surface of the substrate, the surface facing the light receiving surface. The present technology can be applied to back-illuminated solid-state imaging devices and the like, for example.

### TECHNICAL FIELD

The present technology relates to solid-state imaging devices, and more particularly, to a solid-state imaging device capable of increasing sensitivity while reducing color mixing degradation, for example.

### BACKGROUND ART

For solid-state imaging devices, a minute uneven structure at an interface on the light receiving surface side of a silicon layer having photodiodes formed therein has been suggested as a structure for preventing reflection of incident light (see Patent Documents 1 and 2, for example).

### CITATION LIST

### Patent Documents

Patent Document 1: Japanese Patent Application Laid-Open No. 2010-272612
Patent Document 2: Japanese Patent Application Laid-Open No. 2013-33864

### SUMMARY OF THE INVENTION

### Problems to be Solved by the Invention

The minute uneven structure can prevent reflection of incident light and increase sensitivity, but also enhances scattering of light. As a result, the amount of light leaking into the adjacent pixels becomes larger, and there is a possibility that color mixing degradation will become greater.

The present disclosure is made in view of such circumstances, and aims to increase sensitivity while reducing color mixing degradation.

### Solutions to Problems

A first solid-state imaging device of one aspect of the present technology includes: a substrate; a plurality of photoelectric conversion regions formed in the substrate; a trench that is formed between the photoelectric conversion regions, and penetrates the substrate; and a recessed region that includes a plurality of concave portions, and is provided above the photoelectric conversion regions and on the side of the light receiving surface of the substrate, in which the substrate includes a III-V semiconductor or polycrystalline SiXGe (1-x) (x=0 to 1).

A second solid-state imaging device of one aspect of the present technology includes: a substrate; a plurality of photoelectric conversion regions formed in the substrate; a trench that is formed between the photoelectric conversion regions, and penetrates the substrate; a recessed region that includes a plurality of concave portions, and is provided above the photoelectric conversion regions and on the side of the light receiving surface of the substrate; and a metal film that is provided below the photoelectric conversion regions and on the side of a surface of the substrate, the surface facing the light receiving surface.

A third solid-state imaging device of one aspect of the present technology includes: a substrate; a plurality of photoelectric conversion regions formed in the substrate; a color filter that is provided on the upper side of the photoelectric conversion regions; a trench that is formed between the photoelectric conversion regions, and penetrates the substrate; a recessed region that includes a plurality of concave portions, and is provided above the photoelectric conversion regions and on the side of the light receiving surface of the substrate; and a film that is provided above the trench, and has materials having different refractive indexes stacked on the color filter.

A fourth solid-state imaging device of one aspect of the present technology includes: a substrate; a plurality of photoelectric conversion regions formed in the substrate; a color filter that is provided on the upper side of the photoelectric conversion regions; a trench that is formed between the photoelectric conversion regions, and penetrates the substrate; and a recessed region that includes a plurality of concave portions, and is provided above the photoelectric conversion regions and on the side of the light receiving surface of the substrate, in which the color filter has a flat shape on the side of the recessed region.

A fifth solid-state imaging device of one aspect of the present technology includes: a substrate; a plurality of photoelectric conversion regions formed in the substrate; a trench that is formed between the photoelectric conversion regions, and penetrates the substrate; and a recessed region that includes a plurality of concave portions, and is provided above the photoelectric conversion regions and on the side of the light receiving surface of the substrate, in which a color filter and a dual pass filter that has transmission bands for visible light and near-infrared light in a predetermined range are stacked on the photoelectric conversion regions for visible light, and different color filters are stacked on the photoelectric conversion regions for infrared light.

In the first solid-state imaging device of one aspect of the present technology, a substrate, a plurality of photoelectric conversion regions provided in the substrate, a trench that is provided between the photoelectric conversion regions and penetrates the substrate, and a recessed region that includes a plurality of recesses provided on the light receiving surface side of the substrate and is provided above the photoelectric conversion regions are provided. The substrate includes a III-V semiconductor or polycrystalline SiXGe (1-x) (x=0 to 1).

In the second solid-state imaging device of one aspect of the present technology, a substrate, a plurality of photoelectric conversion regions formed in the substrate, a trench that is formed between the photoelectric conversion regions and penetrates the substrate, a recessed region that includes a plurality of concave portions and is provided above the photoelectric conversion regions and on the side of the light receiving surface of the substrate, and a metal film that is provided below the photoelectric conversion regions and on the side of the surface of the substrate facing the light receiving surface are provided.

In the third solid-state imaging device of one aspect of the present technology, a substrate, a plurality of photoelectric conversion regions formed in the substrate, a color filter that is provided on the upper side of the photoelectric conversion regions, a trench that is formed between the photoelectric conversion regions and penetrates the substrate, a recessed region that includes a plurality of concave portions and is provided above the photoelectric conversion regions and on the side of the light receiving surface of the substrate, and a film that is provided above the trench and has materials having different refractive indexes stacked on the color filter are provided.

In the fourth solid-state imaging device of one aspect of the present technology, a substrate, a plurality of photoelectric conversion regions formed in the substrate, a color filter that is provided on the upper side of the photoelectric conversion regions, a trench that is formed between the photoelectric conversion regions and penetrates the substrate, and a recessed region that includes a plurality of concave portions and is provided above the photoelectric conversion regions and on the side of the light receiving surface of the substrate are provided. The color filter has a flat shape on the side of the recessed region.

In the fifth solid-state imaging device of one aspect of the present technology, a substrate, a plurality of photoelectric conversion regions provided in the substrate, a trench that is provided between the photoelectric conversion regions and penetrates the substrate, and a recessed region that includes a plurality of recesses provided on the light receiving surface side of the substrate and is provided above the photoelectric conversion regions are provided. A color filter and a dual pass filter having transmission bands for visible light and near-infrared light in a predetermined range are stacked on the photoelectric conversion regions for visible light. Different color filters are stacked on the photoelectric conversion regions for infrared light.

Note that the solid-state imaging devices and electronic apparatuses may be independent devices, or may be internal blocks in one apparatus.

### BRIEF DESCRIPTION OF DRAWINGS

FIG. 1 is a diagram schematically showing the configuration of a solid-state imaging device according to the present disclosure.

FIG. 2 is a diagram showing an example cross-sectional configuration of pixels according to a first embodiment.

FIG. 3 is a diagram for explaining a recessed region.

FIG. 4 is a diagram showing an example cross-sectional configuration of pixels according to a second embodiment.

FIG. 5 is a diagram showing an example cross-sectional configuration of pixels according to a third embodiment.

FIG. 6 is diagrams for explaining the effects of a pixel structure of the present disclosure.

FIG. 7 is a diagram showing an example cross-sectional configuration of pixels according to a third embodiment.

FIG. 8 is a chart for explaining the manufacturing of pixels according to a fourth embodiment.

FIG. 9 is a diagram showing an example cross-sectional configuration of pixels according to a fifth embodiment.

FIG. 10 is a diagram showing another example cross-sectional configuration of pixels according to a sixth embodiment.

FIG. 11 is a diagram for explaining the functions of a recessed region.

FIG. 12 is a chart for explaining the manufacturing of pixels according to the sixth embodiment.

FIG. 13 is a diagram showing an example cross-sectional configuration of pixels according to a seventh embodiment.

FIG. 14 is a diagram showing an example cross-sectional configuration of pixels according to an eighth embodiment.

FIG. 15 is a diagram showing an example cross-sectional configuration of pixels according to the eighth embodiment.

FIG. 16 is a diagram showing an example planar configuration of pixels according to the eighth embodiment.

FIG. 17 is a diagram showing an example planar configuration of pixels according to the eighth embodiment.

FIG. 18 is a diagram showing an example cross-sectional configuration of pixels according to the eighth embodiment.

FIG. 19 is a diagram showing an example planar configuration of pixels according to the eighth embodiment.

FIG. 20 is a diagram showing an example cross-sectional configuration of pixels according to a ninth embodiment.

FIG. 21 is a diagram for explaining the functions of a waveguide.

FIG. 22 is a diagram showing an example cross-sectional configuration of pixels according to the ninth embodiment.

FIG. 23 is a diagram for explaining the reason for planarization.

FIG. 24 is a diagram showing an example cross-sectional configuration of pixels according to a tenth embodiment.

FIG. 25 is a diagram for explaining the reason for planarization.

FIG. 26 is a diagram showing an example cross-sectional configuration of pixels according to the tenth embodiment.

FIG. 27 is a diagram showing an example cross-sectional configuration of pixels according to the tenth embodiment.

FIG. 28 is a diagram for explaining a pixel array.

FIG. 29 is a diagram for explaining pixel arrays.

FIG. 30 is a diagram for explaining an IR pixel.

FIG. 31 is a diagram for explaining an IR pixel.

FIG. 32 is a diagram showing an example cross-sectional configuration of pixels according to an eleventh embodiment.

FIG. 33 is a diagram showing an example cross-sectional configuration of pixels according to a twelfth embodiment.

FIG. 34 is a diagram showing an example cross-sectional configuration of pixels according to the twelfth embodiment.

FIG. 35 is a block diagram showing an example configuration of an imaging apparatus as an electronic apparatus according to the present disclosure.

FIG. 36 is a diagram schematically showing an example configuration of an endoscopic surgery system.

FIG. 37 is a block diagram showing an example of the functional configurations of a camera head and a CCU.

FIG. 38 is a block diagram schematically showing an example configuration of a vehicle control system.

FIG. 39 is an explanatory diagram showing an example of installation positions of external information detectors and imaging units.

### MODES FOR CARRYING OUT THE INVENTION

The following is a description of modes (hereinafter referred to as embodiments) for carrying out the present technology.

<General Example Configuration of a Solid-State Imaging Device>

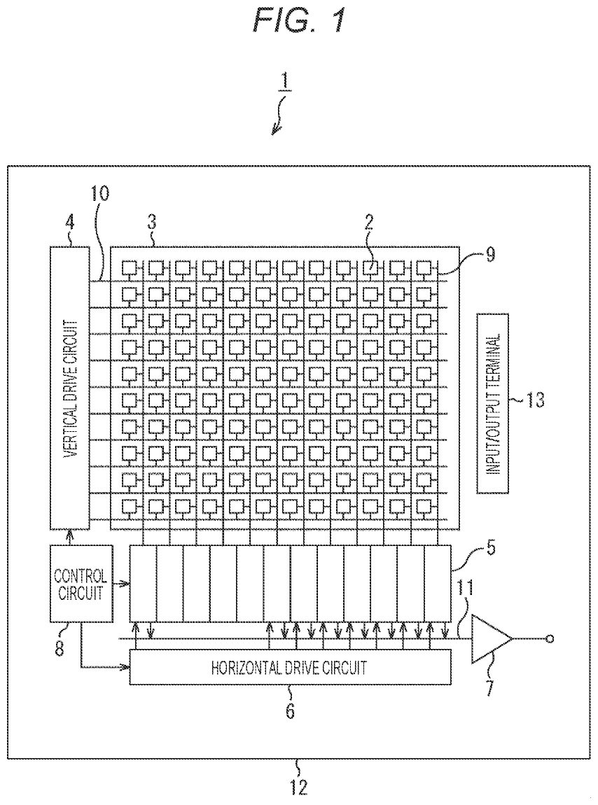

FIG. 1 schematically shows the configuration of a solid-state imaging device according to the present disclosure.

The solid-state imaging device 1 shown in FIG. 1 includes a pixel array unit 3 having pixels 2 arranged in a two-dimensional array on a semiconductor substrate 12 using silicon (Si) as the semiconductor, for example, and a peripheral circuit unit located around the pixel array unit 3. The peripheral circuit unit includes a vertical drive circuit 4, column signal processing circuits 5, a horizontal drive circuit 6, an output circuit 7, a control circuit 8, and the like.

A pixel 2 includes a photodiode as a photoelectric conversion element, and a plurality of pixel transistors. The plurality of pixel transistors is formed with the four MOS transistors: a transfer transistor, a select transistor, a reset transistor, and an amplification transistor, for example.

Alternatively, the pixels 2 may be a sharing pixel structure. This pixel sharing structure includes a plurality of photodiodes, a plurality of transfer transistors, one shared floating diffusion (a floating diffusion region), and each shared one of the other pixel transistors. That is, in the sharing pixel structure, the photodiodes and the transfer transistors that form a plurality of unit pixels share each one of the other pixel transistors.

The control circuit 8 receives an input clock and data that designates an operation mode and the like, and also outputs data such as internal information about the solid-state imaging device 1. Specifically, on the basis of a vertical synchronization signal, a horizontal synchronization signal, and a master clock, the control circuit 8 generates a clock signal and a control signal that serve as the references for operations of the vertical drive circuit 4, the column signal processing circuits 5, the horizontal drive circuit 6, and the like. The control circuit 8 then outputs the generated clock signal and control signal to the vertical drive circuit 4, the column signal processing circuits 5, the horizontal drive circuit 6, and the like.

The vertical drive circuit 4 is formed with a shift register, for example. The vertical drive circuit 4 selects a pixel drive line 10, supplies a pulse for driving the pixels 2 to the selected pixel drive line 10, and drives the pixels 2 on a row-by-row basis. Specifically, the vertical drive circuit 4 sequentially selects and scans the respective pixels 2 of the pixel array unit 3 on a row-by-row basis in the vertical direction, and supplies pixel signals based on signal charges generated in accordance with the amounts of light received in the photoelectric conversion units of the respective pixels 2, to the column signal processing circuits 5 through vertical signal lines 9.

The column signal processing circuits 5 are provided for the respective columns of the pixels 2, and perform signal processing such as denoising, on a column-by-column basis, on signals that are output from the pixels 2 of one row. For example, the column signal processing circuits 5 perform signal processing such as correlated double sampling (CDS) for removing fixed pattern noise inherent to pixels and AD conversion.

The horizontal drive circuit 6 is formed with a shift register, for example, sequentially selects the respective column signal processing circuits 5 by sequentially outputting horizontal scan pulses, and causes the respective column signal processing circuits 5 to output pixel signals to a horizontal signal line 11.

The output circuit 7 performs signal processing on signals sequentially supplied from the respective column signal processing circuits 5 through the horizontal signal line 11, and outputs the processed signals. The output circuit 7 might perform only buffering in some cases, or might perform black level control, column variation correction, various kinds of digital signal processing, and the like in other cases, for example. An input/output terminal 13 exchanges signals with the outside.

The solid-state imaging device 1 having the configuration as above is a so-called column AD-type CMOS image sensor in which the column signal processing circuits 5 that perform CDS and AD conversion are provided for the respective pixel columns.

Also, the solid-state imaging device 1 is a back-illuminated MOS solid-state imaging device in which light enters from the back surface side on the opposite side from the front surface side of the semiconductor substrate 12 having the pixel transistors formed thereon.

### First Embodiment

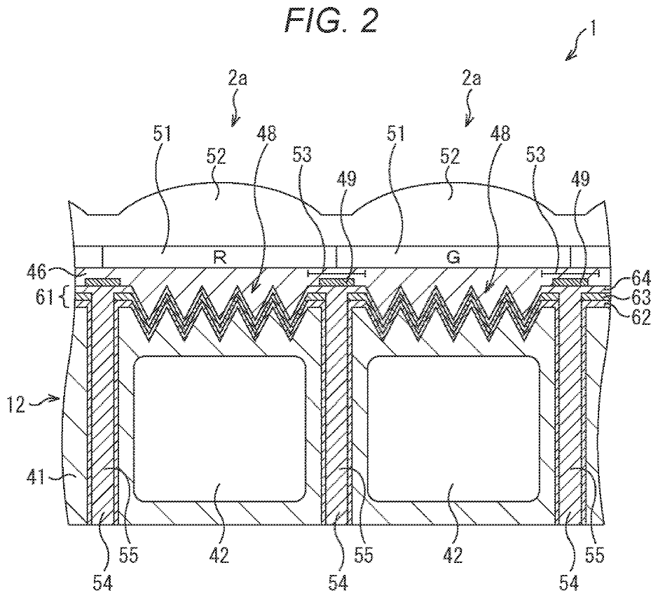

FIG. 2 is a diagram showing an example cross-sectional configuration of pixels 2a according to a first embodiment.

A solid-state imaging device 1 includes a semiconductor substrate 12, and a multilayer wiring layer and a support substrate (both not shown) that are formed on the front surface side of the semiconductor substrate 12.

The semiconductor substrate 12 is formed with silicon (Si), for example, and has a thickness of 1 to 6 μm, for example. In the semiconductor substrate 12, N-type (second-conductivity-type) semiconductor regions 42 for the respective pixels 2a are formed in P-type (first-conductivity-type) semiconductor regions 41, for example, so that photodiodes PD are formed on a pixel-by-pixel basis. The P-type semiconductor regions 41 provided on both the front and back surfaces of the semiconductor substrate 12 also serve as hole charge storage regions for reducing dark current.

As shown in FIG. 2, the solid-state imaging device 1 is formed by stacking an antireflective film 61, a transparent insulating film 46, color filter layers 51, and on-chip lenses 52 on the semiconductor substrate 12 in which the N-type semiconductor regions 42 forming the photodiodes PD are formed for the respective pixels 2a.

At an interface (a light-receiving-surface-side interface) of the P-type semiconductor regions 41 that serve as the charge storage regions on the upper side of the N-type semiconductor regions 42, the antireflective film 61 that prevents reflection of incident light is formed with recessed regions 48 having minute uneven structures.

The antireflective film 61 has a stack structure in which a fixed charge film and an oxide film are stacked, for example, and a high-dielectric-constant (high-k) insulating thin film formed by atomic layer deposition (ALD), for example, may be used as the antireflective film 61. Specifically, hafnium oxide (HfO2), aluminum oxide (Al2O3), titanium oxide (TiO2), strontium titanium oxide (STO), or the like may be used. In the example shown in FIG. 2, the antireflective film 61 is formed with a stack of a hafnium oxide film 62, an aluminum oxide film 63, and a silicon oxide film 64.

Further, light blocking films 49 are formed between the pixels 2a so as to be stacked on the antireflective film 61. Single-layer metal films of titanium (Ti), titanium nitride (TiN), tungsten (W), aluminum (Al), tungsten nitride (WN), or the like are used as the light blocking films 49. Alternatively, laminated films of these metals (laminated films of titanium and tungsten, a laminated film of titanium nitride and tungsten, or the like, for example) may be used as the light blocking films 49.

The transparent insulating film 46 is formed on the entire back surface side (the light incident face side) of the P-type semiconductor regions 41. The transparent insulating film 46 includes a material that transmits light, has insulation properties, and has a refractive index n1 that is smaller than the refractive index n2 of the semiconductor regions 41 and 42 (n1<n2). Examples of materials that can be used for the transparent insulating film 46 include silicon oxide (SiO2), silicon nitride (SiN), silicon oxynitride (SiON), hafnium oxide (HfO2), aluminum oxide (Al2O3), zirconium oxide (ZrO2), tantalum oxide (Ta2O5), titanium oxide (TiO2), lanthanum oxide (La2O3), praseodymium oxide (Pr2O3), cerium oxide (CeO2), neodymium oxide (Nd2O3), promethium oxide (Pm2O3), samarium oxide (Sm2O3), europium oxide (Eu2O3), gadolinium oxide (Gd2O3), terbium oxide (Tb2O3), dysprosium oxide (Dy2O3), holmium oxide (Ho2O3), thulium oxide (Tm2O3), ytterbium oxide (Yb2O3), lutetium oxide (Lu2O3), yttrium oxide (Y2O3), a resin, and combinations of these materials.

The color filter layers 51 are formed on the upper side of the transparent insulating film 46 including the light blocking films 49. A red, green, or blue color filter layer 51 is formed for each pixel. The color filter layers 51 are formed by spin coating with a photosensitive resin containing coloring matter such as colorant or pigment, for example. The respective colors of red, green, and blue are arranged according to the Bayer array, for example, but may be arranged by some other arrangement method. In the example shown in FIG. 2, a green (G) color filter layer 51 is formed in the pixel 2a on the right side, and a red (R) color filter layer 51 is formed in the pixel 2a on the left side.

On the upper side of the color filter layers 51, the on-chip lenses 52 are formed for the respective pixels 2a. The on-chip lenses 52 are formed with a resin material such as styrene resin, acrylic resin, styrene-acrylic copolymer resin, or siloxane resin, for example. Incident light is condensed in the on-chip lenses 52, and the condensed light efficiently enters the photodiodes PD via the color filter layers 51.

For the pixel 2a shown in FIG. 2, pixel separation portions 54 that separate the pixels 2a from one another are formed in the semiconductor substrate 12. The pixel separation portions 54 are created by forming trenches that penetrate the semiconductor substrate 12 between the N-type semiconductor regions 42 forming the photodiodes PD, forming the aluminum oxide film 63 on the inner surfaces of the trenches, and further burying insulators 55 in the trench when the silicon oxide film 64 is formed.

Note that the portion of the silicon oxide film 64 filling the pixel separation portions 54 can be filled with polysilicon. FIG. 2 illustrates a case where the silicon oxide film 64 is formed integrally with the insulators 55.

As such pixel separation portions 54 are formed, adjacent pixels 2a are electrically isolated from one another completely by the insulators 55 buried in the trenches. With this arrangement, it is possible to prevent the electric charge generated inside the semiconductor substrate 12 from leaking into the adjacent pixels 2a.

Further, in the pixels 2a according to the first embodiment, regions having a predetermined width in which the recessed regions 48 are not formed between the pixels 2a at the light-receiving-surface-side interface of the semiconductor substrate 12, and thus, flat portions 53 are formed. Minute recessed structures are formed to provide the recessed regions 48, and the structures are not formed in the regions between the pixels 2a to leave flat surfaces. Thus, the flat portions 53 are formed. As the pixel structures including the flat portions 53 are formed in this manner, it is possible to reduce generation of diffracted light in the region (the pixel separation region) having a predetermined width in the vicinity of another adjacent pixel 2a, and prevent the occurrence of color mixing.

That is, it is known that, in a case where the recessed regions 48 are formed in the semiconductor substrate 12, diffraction of vertically incident light occurs, the component of the diffracted light becomes larger with increase in the interval (pitch) between the concave portions, for example, and the ratio of light entering other adjacent pixel 2 becomes higher.

In the solid-state imaging device 1, on the other hand, the flat portions 53 are formed in the regions having a predetermined width between the pixels 2a where diffracted light easily leaks into other adjacent pixels 2a, so that diffraction of vertical incident light does not occur at the flat portions 53. Thus, it is possible to prevent the occurrence of color mixing.

Each pixel 2a of the pixel array unit 3 of the solid-state imaging device 1 is designed as described above.

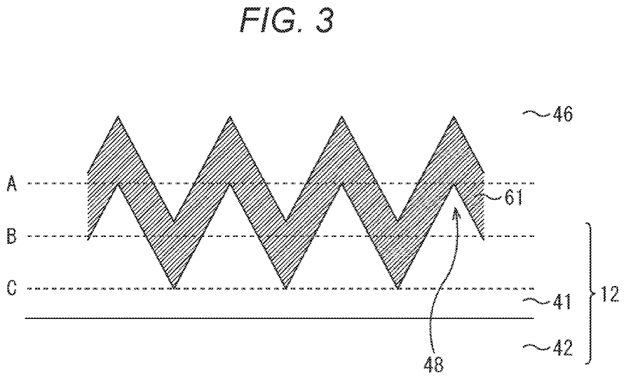

Referring now to FIG. 3, the recessed regions 48 are further explained. The recessed regions 48 are regions in which minute irregularities are formed, but the concave portions and the convex portions vary depending on at which position the plane to serve as the reference is set (this plane will be hereinafter referred to as the reference plane).

Also, the recessed regions 48 are the regions that have minute uneven structures and are formed at the interface (the light-receiving-surface-side interface) of the P-type semiconductor regions 41 on the upper side of the N-type semiconductor regions 42 to be the charge storage regions. The uneven structures are formed on the light receiving surface side of the semiconductor region 42 or the semiconductor substrate 12. Accordingly, the reference plane can be a predetermined surface of the semiconductor substrate 12, and a case where part of the semiconductor substrate 12 is used as the reference plane is described as an example herein.

The recessed region 48 shown in FIG. 3 is formed in a triangular shape in a cross-sectional view. As the recessed region 48 shown in FIG. 3 is formed in a triangular shape in a cross-sectional view, the plane connecting vertexes is set as an example of the reference plane.

In the cross-sectional view, the plane that includes the line connecting the vertexes located on the side of the transparent insulating film 46 among the vertexes of the triangular shapes of the recessed region 48 is defined as a reference plane A. Of the vertices of the triangular shapes of the recessed region 48, the plane including the line connecting the vertexes on the bottom side, which are the vertexes on the side of the semiconductor region 42, is defined as a reference plane C. A reference plane B is a plane between the reference plane A and the reference plane C.

In a case where the reference plane A is used as the reference, the shape of the recessed region 48 is a shape having triangular (valley-like) concave portions facing downward with respect to the reference plane A. That is, in a case where the reference plane A is used as the reference, valley regions are located on the lower side of the reference plane A, and the valley regions correspond to concave portions. Accordingly, the recessed region 48 is a region in which minute concave portions are formed. Further, in other words, in a case where the reference plane A is used as the reference, the recessed region 48 can be regarded as a region in which concave portions are formed between a vertex of a triangle and vertexes of the adjacent triangles, and minute concave portions are formed.

In a case where the reference plane C is used as the reference, the shape of the recessed region 48 is a shape having triangular (peak-like) convex portions facing upward with respect to the reference plane C. That is, in a case where the reference plane C is used as the reference, peak regions are located on the upper side of the reference plane C, and the peak regions correspond to convex portions. Accordingly, the recessed region 48 is a region in which minute convex portions are formed. Further, in other words, in a case where the reference plane C is used as the reference, the recessed region 48 can be regarded as a region in which convex portions are formed between the vertexes of the bottom sides of the triangles, and minute convex portions are formed.

In a case where the reference plane B is used as the reference, the shape of the recessed region 48 is a shape having concave portions and convex portions (valleys and peaks) with respect to the reference plane B. That is, in a case where the reference plane B is used as the reference, there are concave portions that are valleys on the lower side of the reference plane B, and there are convex portions that are peaks on the upper side of the reference plane B. Accordingly, this region can be regarded as a region formed with minute concave and convex portions.

As described above, even if the shape of the recessed region 48 is a zigzagged shape having peaks and valleys as shown in FIG. 3, the recessed region 48 can be defined as a region formed with minute concave portions, a region formed with minute convex portions, or a region formed with minute concave and convex portions, depending on at which position the reference plane is set in a cross-sectional view of the pixel 2.

Also, in the recessed region 48 shown in FIG. 3, in a case where the reference plane is the interface between the transparent insulating film 46 and the color filter layer 51, for example, the recessed region 48 has a shape having concave regions (valleys), and accordingly, can be regarded as a region formed with minute concave portions.

Further, in a case where the reference plane is the boundary plane between the P-type semiconductor regions 41 and the N-type semiconductor region 42, the recessed region 48 has a shape having protruding regions (peaks), and accordingly, can be regarded as a region formed with minute convex portions.

As described above, in a cross-sectional view of the pixel 2, a predetermined flat plane is set as the reference plane, and the shape of the recessed region 48 can also be expressed as a shape having valleys or a shape having peaks with respect to the reference plane.

Further, in a case where the flat portions 53 are formed between the pixels 2, the flat portions 53 are regions formed by providing regions having a predetermined width in which the recessed regions 48 are not formed between the pixels 2 at the light-receiving-surface-side interface of the semiconductor substrate 12. The plane including the flat portions 53 may be used as the reference plane.

Referring to FIG. 2, in a case where the plane including the flat portions 53 is set as the reference plane, the recessed regions 48 can be regarded as regions having concave portions below the reference plane, or as regions having valley-like portions. Therefore, the recessed regions 48 can be regarded as regions in which minute concave portions are formed.

As described above, the recessed regions 48 are regions that can be expressed as regions formed with minute concave portions, regions formed with minute convex portions, or regions formed with minute concave and convex portions, depending on at which position the reference plane is set in a cross-sectional view of the pixels 2.

In the description below, explanation will be continued on the assumption that the recessed regions 48 are regions formed with minute concave portions. However, the recessed regions 48 might be expressed as regions formed with minute convex portions, or regions formed with minute concave and convex portions, as described above.

### Second Embodiment

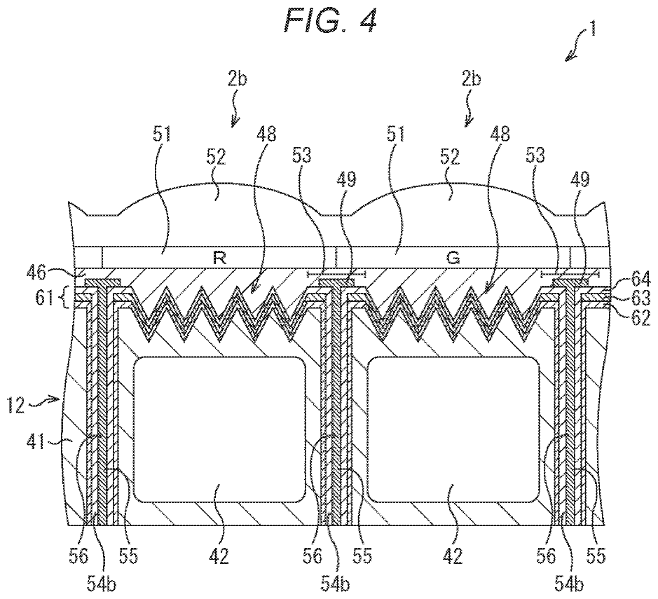

FIG. 4 is a diagram showing an example cross-sectional configuration of pixels 2b according to a second embodiment.

In FIG. 4, the basic configuration of a solid-state imaging device 1 is similar to the configuration shown in FIG. 2. In pixels 2b according to the second embodiment, pixel separation portions 54b that completely isolate the pixels 2b from one another is formed in the semiconductor substrate 12.

The pixel separation portions 54b are formed by digging trenches penetrating the semiconductor substrate 12 between the N-type semiconductor regions 42 forming the photodiodes PD, burying insulators 55 (the silicon oxide film 64 in FIG. 4) in the inner surfaces of the trenches, and further burying light shields 56 when the light blocking films 49 are formed inside the insulators 55. The light shields 56 include a metal having a light blocking effect, and are formed integrally with the light blocking films 49.

As such pixel separation portions 54b are formed, adjacent pixels 2b are electrically isolated from one another by the insulators 55 buried in the trenches, and are optically isolated from one another by the light shields 56. As a result, the electric charge generated inside the semiconductor substrate 12 can be prevented from leaking into the adjacent pixels 2b, and light from oblique directions can also be prevented from leaking into the adjacent pixels 2b.

Furthermore, in the pixels 2b according to the second embodiment, pixel structures including the flat portions 53 are adopted. Thus, it is possible to reduce generation of diffracted light in the pixel separation regions, and prevent the occurrence of color mixing.

### Third Embodiment

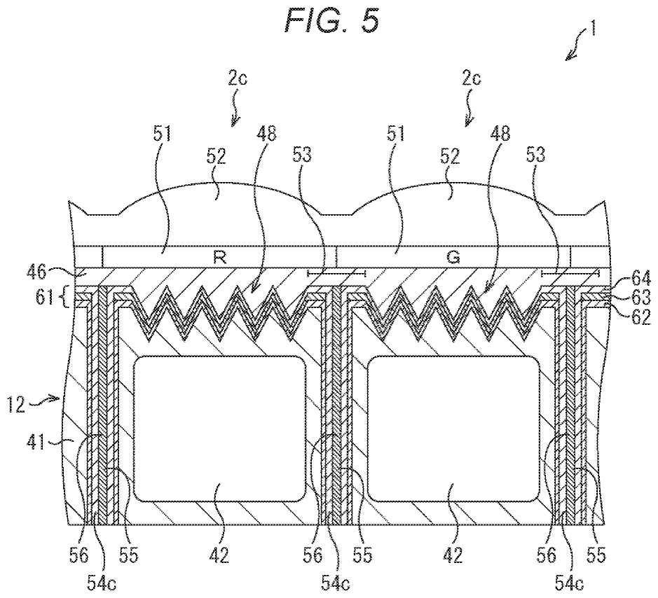

FIG. 5 is a diagram showing an example cross-sectional configuration of pixels 2c according to a third embodiment.

In FIG. 5, the basic configuration of a solid-state imaging device 1 is similar to the configuration shown in FIG. 2. In pixels 2c according to the third embodiment, pixel separation portions 54c that completely isolate the pixels 2c from one another is formed in the semiconductor substrate 12.

The pixel separation portions 54c of the pixels 2c according to the third embodiment differ from those of the pixels 2b according to the second embodiment in that the light blocking films 49 are not provided at the flat portions 53.

As such pixel separation portions 54c are formed, adjacent pixels 2c are electrically isolated from one another by the insulators 55 buried in the trenches, and are optically isolated from one another by the light shields 56. As a result, the electric charge generated inside the semiconductor substrate 12 can be prevented from leaking into the adjacent pixels 2c, and light from oblique directions can also be prevented from leaking into the adjacent pixels 2c.

Furthermore, in the pixels 2c according to the third embodiment, pixel structures including the flat portions 53 are adopted. Thus, it is possible to reduce generation of diffracted light in the pixel separation regions, and prevent the occurrence of color mixing.

<Effects of Provision of the Recessed Regions>

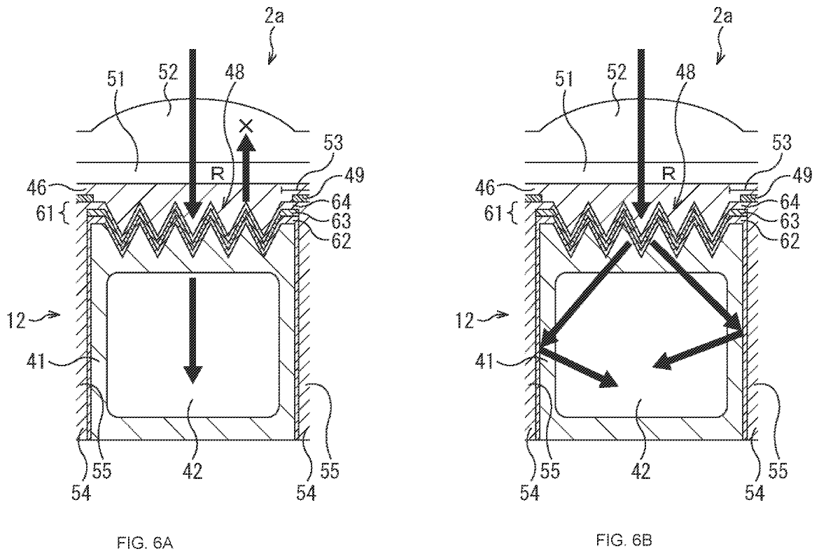

The effects to be achieved in the pixels 2 by virtue of the recessed regions 48 provided in the pixels 2 are now described with reference to FIG. 6. FIG. 6 is diagrams for explaining the effects of the pixel structure of the pixels 2a shown in FIG. 2.

A of FIG. 6 is a diagram for explaining the effects of the antireflective film 61 having the recessed regions 48. As the antireflective film 61 has an uneven structure, reflection of incident light is prevented. Thus, the sensitivity of the solid-state imaging device 1 can be increased.

B of FIG. 6 is a diagram for explaining the effects of the pixel separation portions 54 having a trench structure. In a conventional case where the pixel separation portions 54 are not provided, incident light scattered by the antireflective film 61 might pass through the photoelectric conversion regions (the semiconductor regions 41 and 42). The pixel separation portions 54 have an effect to reflect incident light scattered by the antireflective film 61 and confine the incident light in the photoelectric conversion regions. As a result, the optical range for absorbing silicon is extended, so that sensitivity can be increased.

Where the refractive index of the pixel separation portions 54 is n1=1.5 (corresponding to SiO2), and the refractive index of the semiconductor regions 41 having the photoelectric conversion regions formed therein is n2=4.0, a waveguide effect (the photoelectric conversion regions being the core, the pixel separation portions 54 being the clad) is caused by the refractive index difference (n1<n2), and thus, incident light is confined in the photoelectric conversion regions. The recessed regions 48 have a disadvantage in degrading color mixing due to light scattering. However, combined with the pixel separation portions 54, the recessed regions 48 can cancel the degradation of color mixing, and further, the incident angle of light traveling in the photoelectric conversion regions becomes greater. Thus, photoelectric conversion efficiency is increased.

Furthermore, as the optical range for absorbing silicon can be extended, a structure for increasing the optical path length can be obtained, and even incident light having a long wavelength can be efficiently condensed in the photodiodes PD. Thus, sensitivity can be increased even with respect to incident light having a long wavelength. Because a long optical path length can be obtained, sensitivity can be increased even with respect to infrared light (IR) having a long wavelength, without an increase in the thickness of the pixels 2, or an increase in the thickness of the semiconductor substrate 12.

In a case where the semiconductor substrate 12 of the pixels 2 is formed with silicon (Si) and receives light in the infrared band, there is a possibility that the quantum efficiency of the silicon will drop. For example, it might become difficult to ensure a high sensitivity, such as QE>30%, with respect to near-infrared light having a wavelength of about 940 nm. Therefore, a material having a high photoelectric conversion efficiency in the infrared band is used so that a higher quantum efficiency than that with silicon can be ensured.

### Fourth Embodiment

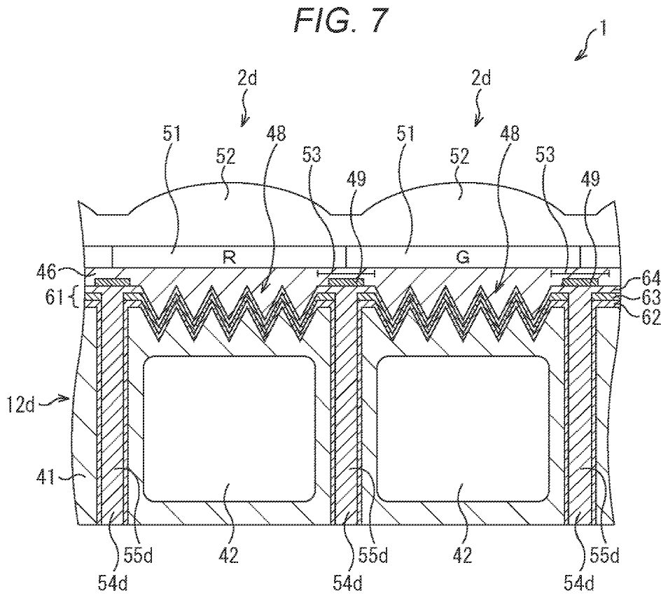

FIG. 7 shows an example configuration of pixels 2d according to a fourth embodiment. The structure of the pixels 2d according to the fourth embodiment can be the same as the structure of the pixels 2a according to the first embodiment shown in FIG. 2.

The photoelectric conversion regions (the regions including the p-type semiconductor regions 41 and the n-type semiconductor regions 42) of the pixels 2d according to the fourth embodiment, or the semiconductor substrate 12, is formed with a III-V semiconductor or polycrystalline SiXGe (1-x) (x=0 to 1).

Examples of the III-V semiconductor include indium phosphide (InP), indium arsenide (InAs), indium arsenide phosphide (InAsP), indium gallium arsenide (InGaAs), gallium nitride (GaN), and indium gallium arsenide (InGaAsN).

The III-V semiconductor or the polycrystalline SiXGe (1-x) (x=0 to 1) is a material having a high photoelectric conversion efficiency in the infrared wavelength band. As such a material having a high photoelectric conversion efficiency in the infrared wavelength band is used for the semiconductor substrate 12d, light in the infrared wavelength band can be subjected to more efficient photoelectric conversion in the pixels 2 having the recessed regions 48 formed therein.

In the fourth embodiment, the pixels may not include the light blocking films 49, like the pixels 2c of the third embodiment.

In a case where the pixels 2d according to the fourth embodiment are pixels that receive light in the infrared wavelength band, the color filter layers 51 may be filters that efficiently pass infrared light, or the color filter layers 51 may not be provided in the structure, so that the pixels 2d are appropriately optimized for infrared light.

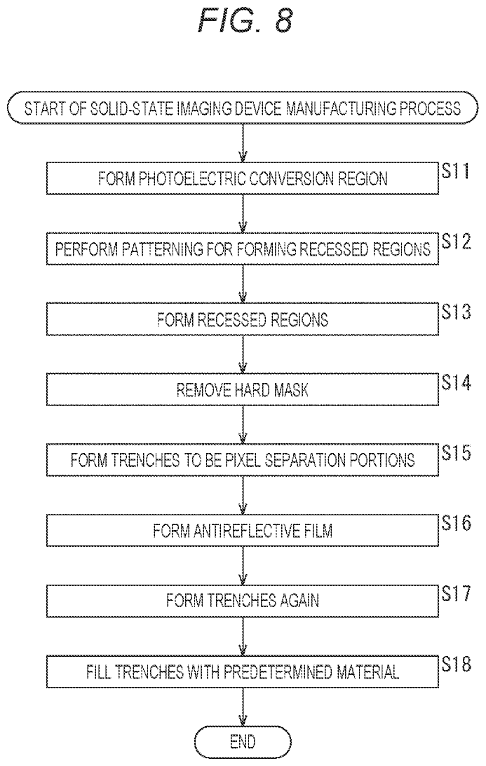

The manufacturing of the pixels 2d shown in FIG. 7 is now described with reference to the flowchart shown in FIG. 8. The manufacturing of the recessed regions 48 and the pixel separation portions 54 of the pixels 2d are additionally described herein.

In step S11, the photoelectric conversion regions are formed. A substrate formed with a III-V semiconductor or polycrystalline SiXGe (1-x) (x=0 to 1) is prepared as the semiconductor substrate 12, and ion implantation is performed to form the photoelectric conversion regions.

In step S12, patterning for forming the recessed regions 48 is performed. Plasma enhanced tetra ethyl ortho silicate glass (p-TEOS) is applied onto the upper surfaces of the P-type semiconductor regions 41 on the back surface side of the semiconductor substrate 12, and is subjected to patterning by a lithography technique so as to form the open portions that are to be the recessed regions 48. Thus, a hard mask is formed.

In step S12, on the basis of the hard mask, a dry etching process or a wet etching process is performed on the semiconductor substrate 12, to form (the irregular shapes to be) the recessed regions 48. In a case where the semiconductor substrate 12 is formed with a III-V semiconductor, for example, etching is performed by anisotropic wet etching. As for the solution to be used in the wet etching, a solution in which citric acid/H2O2/H20 are blended at a predetermined blending ratio can be used, for example.

Alternatively, in a case where the semiconductor substrate 12 is formed with polycrystalline SiXGe (1-x) (x=0 to 1), for example, chemical dry etching can be performed.

In step S14, after the irregular shapes to be the recessed regions 48 are formed, the hard mask provided to form the irregular shapes is removed. After the removal of the hard mask, peak sharpening is performed to form triangular shapes like those of the recessed regions 48 shown in FIG. 7. Also, valley rounding is performed to create the portions corresponding to the flat portions 53.

In step S15, the trenches to be the pixel separation portions 54 are formed. To form the trenches to be the pixel separation portions 54, p-TEOS is applied onto the upper surfaces of the P-type semiconductor regions 41 on the back surface side of the semiconductor substrate 12, and is subjected to patterning by a lithography technique so as to form opening portions at the portions to be the trenches.

After that, a dry etching process is performed, to form the portions to be the trenches. After the trench structures of the pixel separation portions 54 are formed, the hard mask is removed.

Note that, in a case where it is necessary to dig trenches deep in the semiconductor substrate 12 at the time of formation of the trenches, the trenches may be formed by an anisotropic etching process. As the trenches are formed by an anisotropic etching process, the pixel separation portions 54 can have trench shapes that are not tapered.

In step S16, the antireflective film 61 (the recessed regions 48) is formed. In a case where pixel separation portions 54d are formed so as to be filled only with the insulators 55 like the pixel separation portions 54a of the pixel 2a (FIG. 2) of the first embodiment, the hafnium oxide film 62 and the aluminum oxide film 63 are sequentially stacked by the atomic layer deposition (ALD) method in step S16.

In step S17, trenches are formed again. As the process in step S16 is performed, the trenches formed in step S15 are filled with the hafnium oxide film 62 and the aluminum oxide film 63. The aluminum oxide film 63 is removed, and trenches for forming the insulators 55 are formed in step S17.

In step S18, the trenches formed again are filled with silicon oxide, and the silicon oxide is also formed as a film on the region in which the hafnium oxide film 62 and the aluminum oxide film 63 to constitute the antireflective film 61 are stacked. By such a process, the pixel separation portions 54d and the antireflective film 61 are formed.

The pixels 2d manufactured in this manner can particularly increase the photoelectric conversion efficiency in the infrared wavelength band.

### Fifth Embodiment

In the fourth embodiment described above, to increase the photoelectric conversion efficiency in the infrared wavelength band, the material of the photoelectric conversion regions is a material that easily absorbs light in the infrared wavelength band. Pixels 2 having a structure that further increases the photoelectric conversion efficiency in the infrared wavelength band are now described.

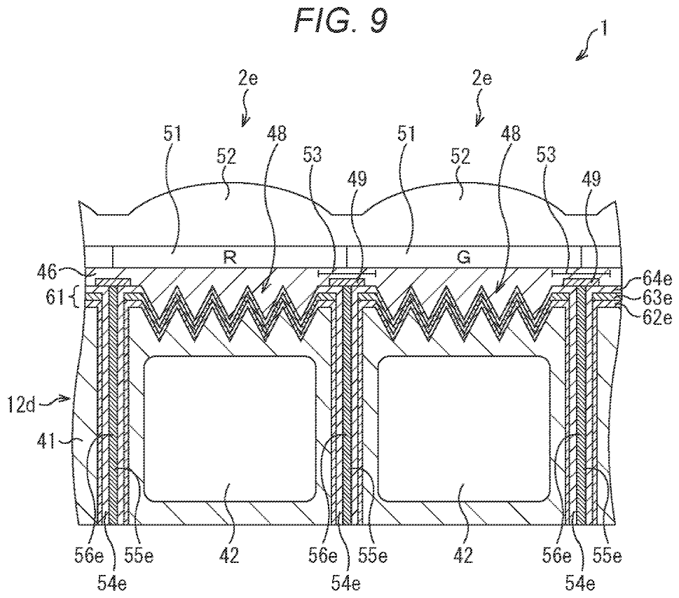

FIG. 9 is a diagram showing an example configuration of pixels 2e according to a fifth embodiment. The pixels 2e according to the fifth embodiment has a configuration in which the pixels 2d (FIG. 7) according to the fourth embodiment are combined with the pixels 2b (FIG. 4) according to the second embodiment.

The pixels 2e according to the fifth embodiment can have the same structure as the pixels 2b (FIG. 4) according to the second embodiment.

The photoelectric conversion regions (the regions including the p-type semiconductor regions 41 and the n-type semiconductor regions 42) of the pixels 2e according to the fifth embodiment is formed with a III-V semiconductor or polycrystalline SiXGe (1-x) (x=0 to 1), like the pixels 2d (FIG. 7) according to the fourth embodiment.

In the pixels 2e according to the fifth embodiment, a material having a high photoelectric conversion efficiency in the infrared wavelength band is also used for the semiconductor substrate 12e. Accordingly, light in the infrared wavelength band can be subjected to more efficient photoelectric conversion in the pixels 2 having the recessed regions 48 formed therein.

Further, as described above, as the pixel separation portions 54 are formed in the pixels 2, it is possible to achieve an effect to reflect incident light scattered by the antireflective film 61 and confine the incident light in the photoelectric conversion regions. For example, the structure of the pixel separation portions 54 can be designed like the pixel separation portions 54b of the pixels 2b according to the second embodiment shown in FIG. 4.

Referring back to FIG. 4, the pixel separation portions 54b have a structure in which the hafnium oxide film 62, the silicon oxide film 64, and the light shields 56 are stacked in this order from the side of the photoelectric conversion regions (the P-type semiconductor regions 41).

Further, to efficiently reflect light in the infrared wavelength band and prevent color mixing in the adjacent pixels, pixel separation portions 54e may have a structure in which a back-surface antireflective film 62e, a low refractive index material 64e, and a high refractive index material 56e are stacked in this order from the side of the photoelectric conversion regions (the P-type semiconductor regions 41), as shown in FIG. 9.

An oxide film can be used as the low refractive index material 64e. Polysilicon, amorphous silicon, or the like can be used as the high refractive index material 56e. Alternatively, instead of the high refractive index material 56e, a high reflectance metal 56e′ may be used. Aluminum (Al), copper (Cu), silver (Ag), platinum (Pt), gold (Au), or the like can be used as the high reflectance material 56e′.

Note that FIG. 9 illustrates a case where the light blocking films 49 and the high refractive index material 56e are different materials from each other, and are not integrally formed in the structure. However, the light blocking films 49 and the high refractive index material 56e (or the light reflectance metal 56e′) may be formed with the same material and be integrally formed, as in the pixels 2b shown in FIG. 4.

Further, the fifth embodiment can be combined with the third embodiment, and may be designed not to include the light blocking films 49.

Furthermore, in a case where the pixels 2e are pixels that receive light in the infrared wavelength band, the color filter layers 51 may be filters that efficiently pass infrared light, or the color filter layers 51 may not be provided in the structure, so that the pixels 2e are appropriately optimized for infrared light.

Like the pixels 2d shown in FIG. 7, the pixels 2e shown in FIG. 9 can be manufactured in a flow based on the flowchart shown in FIG. 8. Referring again to the flowchart in FIG. 8, the manufacturing of the pixels 2e is now described. However, explanation of the same processes will not be unnecessarily repeated.

The processes in steps S11 to S15 are performed, so that the photoelectric conversion regions, part of the recessed regions 48, and part of the pixel separation portions 54e are formed.

In a case where the pixel separation portions 54e are formed with a material suitable for the infrared wavelength band like the pixel separation portions 54e of the pixels 2e (FIG. 9) of the fifth embodiment, the back-surface antireflective film 62e, the aluminum oxide film 63e, and the low refractive index material 64e are sequentially stacked by the atomic layer deposition (ALD) method in step S16.

Note that the low refractive index material 64e is stacked and fills the trenches, after the aluminum oxide film 63e in the pixel separation portions 54e is removed prior to the stacking of the low refractive index material 64e.

In step S17, trenches are formed again. As the process in step S16 is performed, the trenches formed in step S15 are filled with the back-surface antireflective film 62e and the low refractive index material 64e. Trenches for forming light shields 56e (the high refractive index material 56e) are formed in part of the region of the low refractive index material 64e in step S17.

In step S18, the trenches formed again are filled with the high refractive index material 56e forming the light shields 56e, such as polysilicon or amorphous silicon, for example. By such a process, the pixel separation portions 54e and the antireflective film 61 of the pixels 2e (FIG. 9) of the fifth embodiment are formed.

In a case where the high reflectance metal 56e′ is used in place of the high refractive index material 56e, the trenches formed again are filled with the high reflectance material 56e′ forming the light shields 56e, such as aluminum (Al), copper (Cu), silver (Ag), platinum (Pt), or gold (Au), for example, in step S18. By such a process, the pixel separation portions 54e and the antireflective film 61 of the pixels 2e (FIG. 9) of the fifth embodiment are formed.

The pixels 2e manufactured in this manner can particularly increase the photoelectric conversion efficiency in the infrared wavelength band.

### Sixth Embodiment

In the fourth and fifth embodiments described above, to increase the photoelectric conversion efficiency in the infrared wavelength band, the material of the photoelectric conversion regions is a material that easily absorbs light in the infrared wavelength band. Pixels 2 having a structure that further increases the photoelectric conversion efficiency in the infrared wavelength band are now described.

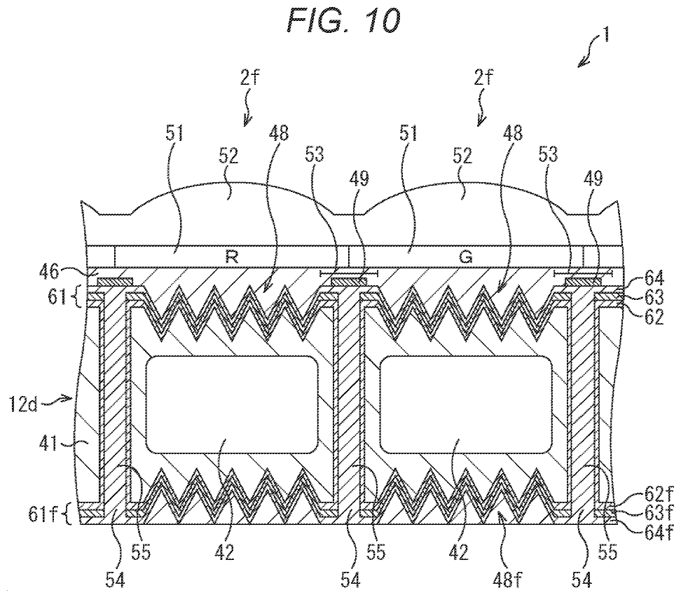

FIG. 10 is a diagram showing an example configuration of pixels 2f according to a sixth embodiment. The pixels 2f according to the sixth embodiment have the same configuration as the pixels 2d (FIG. 7) according to the fourth embodiment, except for further including recessed regions 48f.

The photoelectric conversion regions (the regions including the p-type semiconductor regions 41 and the n-type semiconductor regions 42) of the pixels 2f according to the sixth embodiment is formed with a III-V semiconductor or polycrystalline SiXGe (1-x) (x=0 to 1), like the pixels 2d (FIG. 7) according to the fourth embodiment.

Accordingly, in the pixels 2f according to the sixth embodiment, a material having a high photoelectric conversion efficiency in the infrared wavelength band is also used for the semiconductor substrate 12d. Accordingly, light in the infrared wavelength band can be subjected to more efficient photoelectric conversion in the pixels 2 having the recessed regions 48 formed therein.

Further, in the pixels 2f according to the sixth embodiment shown in FIG. 10, the recessed regions 48f (an antireflective film 61f) are formed not only on the light incident side but also on the side (the wiring layer side) opposite to the light incident side. In other words, the recessed regions 48f (the antireflective film 61f) are formed above and below the photoelectric conversion regions of the pixels 2f.

Like the recessed regions 48 formed on the upper side (the light incident face side) of the photoelectric conversion regions in the drawing, the recessed regions 48f formed on the lower side (the side of the wiring layers not shown in the drawing) of the photoelectric conversion regions in the drawing has a structure in which a hafnium oxide film 62f, an aluminum oxide film 63f, and a silicon oxide film 64f are stacked.

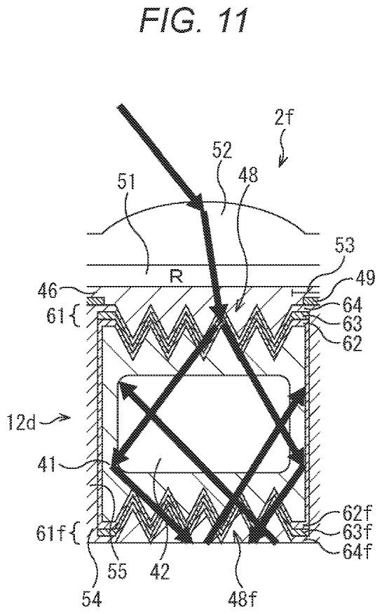

As the recessed regions 48 are formed above and below the photoelectric conversion regions as in the pixels 2f, an effect to confine more incident light in the photoelectric conversion regions can be achieved. Referring now to FIG. 11, the effects to be achieved by providing the recessed regions 48 above and below the photoelectric conversion regions as in the pixels 2f are described.

First, as described above with reference to FIG. 6, the recessed regions 48 are formed on the light incident face side of the photoelectric conversion regions, so that reflection of incident light is prevented. Further, incident light is scattered by the recessed regions 48 formed on the light incident face side of the photoelectric conversion regions, and the scattered light is reflected by the pixel separation portions 54. Thus, the incident light can be confined in the photoelectric conversion regions.

Some of the light that has entered the photoelectric conversion regions reaches the bottom surfaces of the photoelectric conversion regions, while some passes through the photoelectric conversion regions to the wiring layer side. In particular, light in the infrared wavelength band easily reaches the bottom surfaces of the photoelectric conversion regions. Therefore, if the recessed regions 48f are not formed on the wiring layer side, there is a possibility that the light component passing through the photoelectric conversion regions to the wiring layer side will increase.

As shown in FIG. 11, as the recessed regions 48f are also formed on the wiring layer side, light that has reached the wiring layer side can be reflected by the recessed regions 48f, and be returned into the photoelectric conversion regions. Thus, a larger amount of light can be confined in the photoelectric conversion regions.

Furthermore, as the recessed regions 48f are formed on the bottom surface, the optical path length in the photoelectric conversion regions can be made longer, and thus, the optical range for absorbing silicon can be extended. Accordingly, even incident light having a long wavelength can be efficiently condensed in the photoelectric conversion regions, and sensitivity can be increased even with respect to incident light having a long wavelength. Because a long optical path length can be obtained, sensitivity can be increased even with respect to infrared light (IR) having a long wavelength, without an increase in the thickness of the pixels 2, or an increase in the thickness of the semiconductor substrate 12.

Further, as the photoelectric conversion regions are formed with a material having a high photoelectric conversion efficiency in the infrared wavelength band as described above, light in the infrared wavelength band can be subjected to more efficient photoelectric conversion.

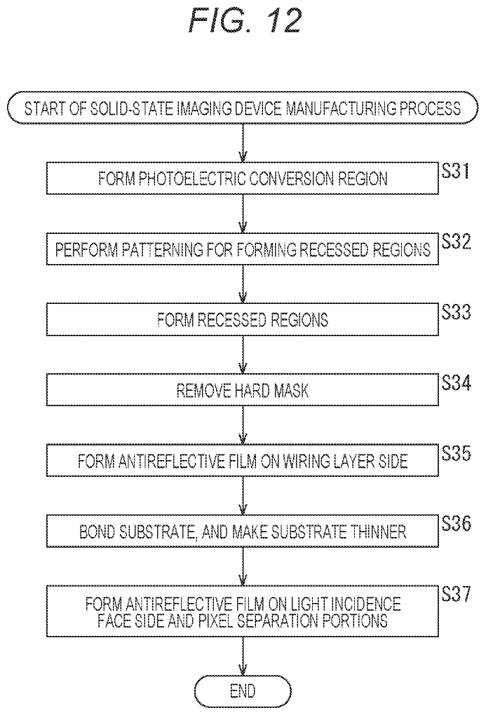

The manufacturing of the pixels 2f shown in FIG. 10 is now described with reference to the flowchart shown in FIG. 12. Since the pixels 2f have a configuration in which the recessed regions 48f are added to the pixels 2d (FIG. 7), the step of forming the recessed regions 48f is added to the process of manufacturing the pixels 2d.

Steps S31 to S34 are processes similar to steps S11 to S14 in the flowchart in FIG. 8, but differ from steps S11 to S14 in that the recessed regions 48f on the wiring layer side are formed. In steps S31 to S34, a substrate formed with a III-V semiconductor or polycrystalline SiXGe (1-x) (x=0 to 1) is prepared as the semiconductor substrate 12, and ion implantation is performed to form the photoelectric conversion regions.

A process for forming the recessed regions 48f on the side at which the wiring layers of the semiconductor substrate 12 having the photoelectric conversion regions formed therein are stacked (the side facing the light incident face side) is performed. Steps S11 to S14 in the flowchart in FIG. 8 are the processes for forming the recessed regions 48 on the light incident face side of the semiconductor substrate 12. However, in a case where the recessed regions 48f are also formed on the wiring layer side, the recessed regions 48f on the wiring layer side are formed before the recessed regions 48 on the light incident face side.

In step S35, the recessed regions 48f (the antireflective film 61f including the recessed regions 48f) on the wiring layer side are formed. The antireflective film 61f on the wiring layer side can be formed basically in a manner similar to that for forming the antireflective film 61 on the light incident face side, and can be formed by a process similar to the process in step S16 (FIG. 8). The process in step S16 has already been described, and therefore, explanation thereof is not made herein.

After the antireflective film 61f on the wiring layer side is formed, a substrate is bonded to the surface side on which the antireflective film 61f has been formed in step S36. The substrate to be bonded is a support substrate, a substrate serving as a wiring layer, a substrate in which a logic circuit is formed, or the like. The bonded substrate is also made thinner.

In step S37, the antireflective film 61f on the light incident face side is formed, and the pixel separation portions 54 are formed. The formation of the antireflective film 61f on the light incident face side and the pixel separation portions 54 is a process similar to steps S12 to S18 in the flowchart in FIG. 8.

The pixels 2f manufactured in this manner can particularly increase the photoelectric conversion efficiency in the infrared wavelength band.

### Seventh Embodiment

In the sixth embodiment described above, to increase the photoelectric conversion efficiency in the infrared wavelength band, the material of the photoelectric conversion regions is a material that easily absorbs light in the infrared wavelength band. Pixels 2 having a structure that further increases the photoelectric conversion efficiency in the infrared wavelength band are now described.

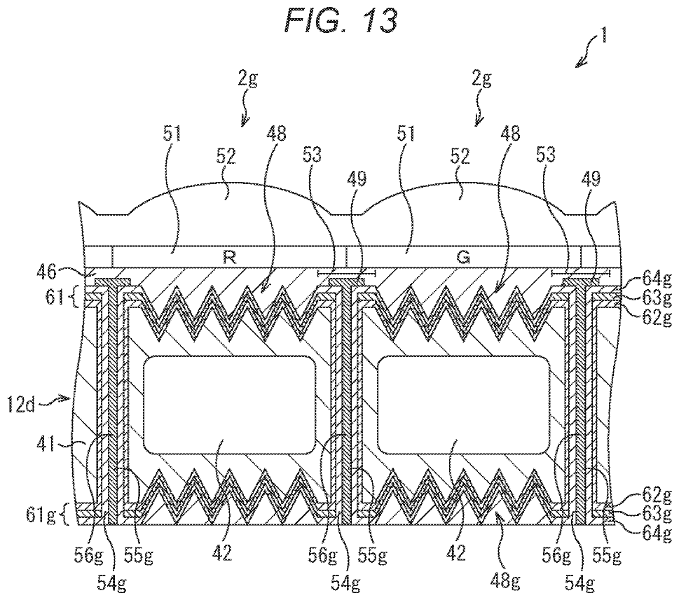

FIG. 13 is a diagram showing an example configuration of pixels 2g according to a seventh embodiment. The pixels 2g according to the seventh embodiment has a configuration in which the pixels 2f (FIG. 10) according to the sixth embodiment are combined with the pixels 2b (FIG. 4) according to the second embodiment.

The photoelectric conversion regions (the regions including the p-type semiconductor regions 41 and the n-type semiconductor regions 42) of the pixels 2g according to the seventh embodiment is formed with a III-V semiconductor or polycrystalline SiXGg (1-x) (x=0 to 1), like the pixels 2d (FIG. 10) according to the sixth embodiment.

Accordingly, in the pixels 2g according to the seventh embodiment, a material having a high photoelectric conversion efficiency in the infrared wavelength band is also used for the semiconductor substrate 12g. Accordingly, light in the infrared wavelength band can be subjected to more efficient photoelectric conversion in the pixels 2 having the recessed regions 48 formed therein.

Further, as described above, as the pixel separation portions 54 are formed in the pixels 2, it is possible to achieve an effect to reflect incident light scattered by the antireflective film 61 and confine the incident light in the photoelectric conversion regions. For example, the structure of the pixel separation portions 54 can be designed like the pixel separation portions 54b of the pixels 2b according to the second embodiment shown in FIG. 4.

Referring back to FIG. 4, the pixel separation portions 54b have a structure in which the hafnium oxide film 62, the silicon oxide film 64, and the light shields 56 are stacked in this order from the side of the photoelectric conversion regions (the P-type semiconductor regions 41).

Further, to efficiently reflect light in the infrared wavelength band and prevent color mixing in the adjacent pixels, pixel separation portions 54g may have a structure in which a back-surface antireflective film 62g, a low refractive index material 64g, and a high refractive index material 56g are stacked in this order from the side of the photoelectric conversion regions (the P-type semiconductor regions 41), as shown in FIG. 13.

An oxide film can be used as the low refractive index material 64g. Polysilicon, amorphous silicon, or the like can be used as the high refractive index material 56g. Alternatively, instead of the high refractive index material 56g, a high reflectance metal 56g′ may be used. Aluminum (Al), copper (Cu), silver (Ag), platinum (Pt), gold (Au), or the like can be used as the high reflectance material 56g′.

Note that FIG. 13 illustrates a case where the light blocking films 49 and the high refractive index material 56g are different materials from each other, and are not integrally formed in the structure. However, the light blocking films 49 and the high refractive index material 56g (or the light reflectance metal 56g′) may be formed with the same material and be integrally formed, as in the pixels 2b shown in FIG. 4.

Further, the seventh embodiment can be combined with the third embodiment, and may be designed not to include the light blocking films 49.

Furthermore, in a case where the pixels 2g are pixels that receive light in the infrared wavelength band, the color filter layers 51 may be filters that efficiently pass infrared light, or the color filter layers 51 may not be provided in the structure, so that the pixels 2g are appropriately optimized for infrared light.

Like the pixels 2f shown in FIG. 10, the pixels 2g shown in FIG. 13 can be manufactured in a flow based on the flowchart shown in FIG. 12. Referring again to the flowchart in FIG. 12, the manufacturing of the pixels 2g is now described. However, explanation of the same processes will not be unnecessarily repeated.

The processing in steps S31 to S37 are performed, so that the photoelectric conversion regions, the recessed regions 48g on the wiring layer side, part of the recessed regions 48g on the light incident face side, and part of the pixel separation portions 54g are formed.

In a case where the pixel separation portions 54g are formed with a material suitable for the infrared wavelength band like the pixel separation portions 54g of the pixels 2g (FIG. 13) of the seventh embodiment, the back-surface antireflective film 62g, the aluminum oxide film 63g, and the low refractive index material 64g are sequentially stacked by the atomic layer deposition (ALD) method in step S16.

Note that the low refractive index material 64g is stacked and fills the trenches, after the aluminum oxide film 63g in the pixel separation portions 54g is removed prior to the stacking of the low refractive index material 64g.

In one procedure in the process in step S37, trenches are formed again. The trenches formed in the previous steps are filled with the back-surface antireflective film 62g and the low refractive index material 64g. Trenches for forming light shields 56g (the high refractive index material 56g) are formed again in part of the region of the low refractive index material 64g.

The trenches formed again are filled with the high refractive index material 56g forming the light shields 56g, such as polysilicon or amorphous silicon, for example. By such a process, the pixel separation portions 54g and the antireflective film 61 of the pixels 2g (FIG. 13) of the seventh embodiment are formed.

In a case where the high reflectance metal 56g′ is used in place of the high refractive index material 56g, the trenches formed again are filled with the high reflectance material 56g′ forming the light shields 56g, such as aluminum (Al), copper (Cu), silver (Ag), platinum (Pt), or gold (Au), for example. By such a process, the pixel separation portions 54g and the antireflective film 61 of the pixels 2g (FIG. 13) of the seventh embodiment are formed.

The pixels 2g manufactured in this manner can particularly increase the photoelectric conversion efficiency in the infrared wavelength band.

### Eighth Embodiment

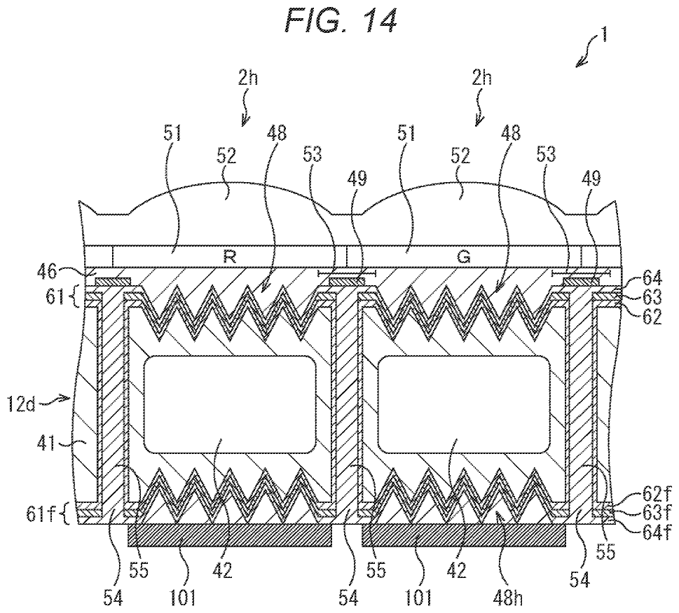

As the recessed regions 48 are also formed on the wiring layer side as in the sixth and seventh embodiments, light leaking to the wiring layer side can be returned into the photoelectric conversion regions, and photoelectric conversion efficiency can be increased. As shown in FIG. 14, reflective films 101 may be further provided on the wiring layer side.

FIG. 14 shows the configuration of pixels 2h according to an eighth embodiment. The pixels 2h have a configuration similar to that of the pixels 2f according to the sixth embodiment or the pixels 2g according to the seventh embodiment, and recessed regions 48h are formed on both the light incident face side and the wiring layer side. Further, the reflective films 101 are stacked on the recessed regions 48h formed on the wiring layer side. FIG. 14 illustrates an example in which the reflective films 101 are stacked on the pixels 2f according to the sixth embodiment.

Note that, in the pixels 2h according to the eighth embodiment, the photoelectric conversion regions (the regions including the p-type semiconductor regions 41 and the n-type semiconductor regions 42) may be formed with silicon (Si), or may be formed with a III-V semiconductor or polycrystalline SiXGe (1-x) (x=0 to 1) as in the fourth embodiment or the like. The embodiment described below can be adopted, regardless of the material of the photoelectric conversion regions.

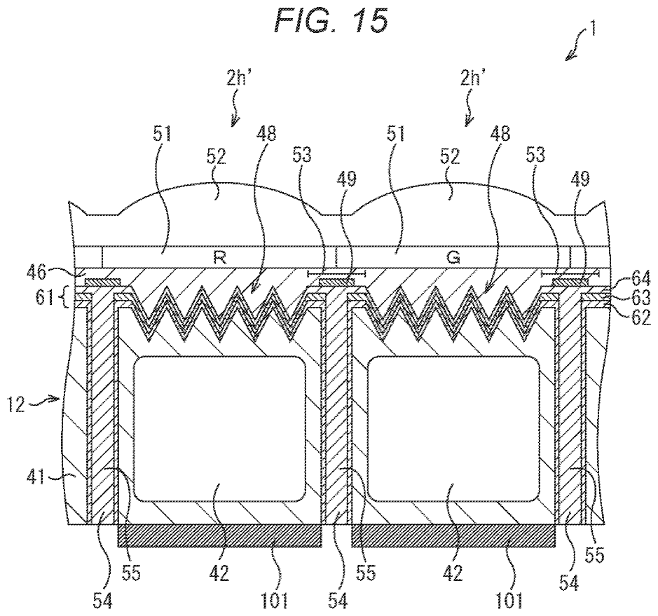

The eighth embodiment can also be applied to the pixels 2a according to the first embodiment. Referring to FIG. 15, the reflective films 101 may also be added on the wiring layer side of pixels 2h′ having a configuration similar to that of the pixels 2a shown in FIG. 2.

The eighth embodiment can be combined with any of the first to seventh embodiments. The eighth embodiment can also be combined with any of the ninth and subsequent embodiments described below. That is, the reflective films 101 can be provided on the wiring layer side of the pixels 2.

The reflective films 101 can be formed with a material having a light blocking effect, such as tungsten (W) or aluminum (Al). Alternatively, the reflective films 101 can be formed with a material that reflects light.

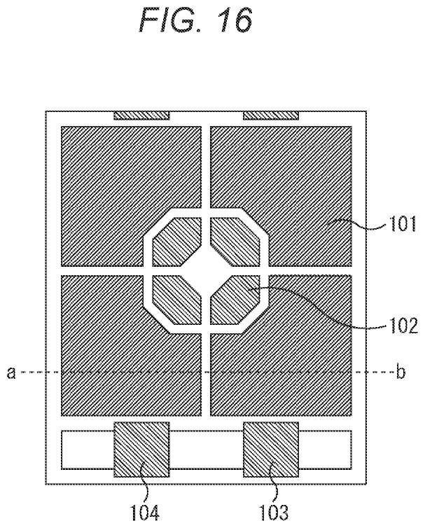

FIG. 16 is a plan view of the pixels 2h shown in FIG. 14 or the pixels 2h′ shown in FIG. 15 (in the description continued below, the pixels 2h will be explained as an example). The plan view shown in FIG. 16 is a view of the pixels 2h as viewed from the wiring layer side. Also, the plan view shown in FIG. 16 illustrates an example of the case of a four-pixel sharing structure in which four pixels 2h are arranged in a 2×2, and the four pixels share a floating gate (FD) and the like. Further, a cross-sectional view taken along a line segment a-b in the plan view shown in FIG. 16 is the cross-sectional view of the pixels 2h shown in FIG. 14.

The reflective films 101 are formed so as to cover the photoelectric conversion regions of the pixels 2h. Also, transfer gates 102 are provided for the respective pixels 2h at the central portion among the pixels 2h arranged in a 2×2. Further, transistors 103 and 104 corresponding to a reset transistor, a select transistor, and an amplification transistor are provided.

As shown in FIG. 16, the reflective films 101 are formed so as to cover the photoelectric conversion regions of the pixels 2h. As the reflective films 101 are formed in this manner, it is possible to prevent light from leaking to the wiring layer side. Light can also be returned into the photoelectric conversion regions, and photoelectric conversion efficiency can also be increased.

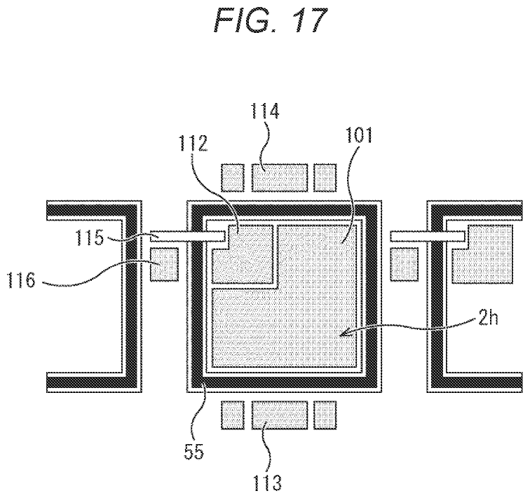

FIG. 17 shows a plan view of the pixels 2h in the case of a two-pixel sharing structure. The plan view shown in FIG. 17 is also a view of the pixels 2h as viewed from the wiring layer side. The reflective films 101, transfer gates 112, reset gates 113, amplification transistors 114, wiring lines 115, and FDs 116 are arranged on the surfaces on the wiring layer side of the pixels 2h shown in FIG. 17.

The pixels 2h shown in FIG. 17 are of a two-pixel sharing type, and each reset gate 113 and each amplification transistor 114 are shared between two pixels. The reset gates 113 of the pixel 2h shown in FIG. 17 are provided on the lower side of the photoelectric conversion regions, and the amplification transistors 114 are provided on the upper side of the photoelectric conversion regions. Further, in the pixels 2h shown in FIG. 17, the reflective films 101 are formed so as to cover the photoelectric conversion regions.

The reflective films 101 are not formed in the regions in which the transfer gates 112 are formed, but the transfer gates 112 prevent light from leaking to the wiring layer side. The photoelectric conversion regions are surrounded by pixel separation portions 54 in which insulators 55 are buried in trenches. In a case where the trenches are formed so as to penetrate the semiconductor substrate 12, the wiring lines 115 for transferring electric charge from the transfer gates 112 to the FDs 116 are formed over the pixel separation portions 54.

As the photoelectric conversion regions are surrounded by the pixel separation portions 54 in this manner, leakage of light between pixels can be prevented, and thus, color mixing between pixels can be prevented. Further, as the reflective films 101 are formed on the wiring layer side of the photoelectric conversion regions, it is possible to prevent light from leaking to the wiring layer side.

A case where the pixels 2h described above have a pixel structure compatible with a global shutter system is now additionally described. In general, a CMOS image sensor is of a rolling shutter type that sequentially reads the respective pixels, and therefore, there is a possibility that image distortion will occur due to a difference in exposure timing. As a countermeasure against this problem, there is a global shutter system suggested for simultaneously reading all pixels by providing charge retaining portions in the pixels. With the global shutter system, it is possible to perform sequential reading after performing all-pixel simultaneous reading on the charge retaining portions. Thus, the same exposure timing can be set for each pixel, and image distortion can be reduced.

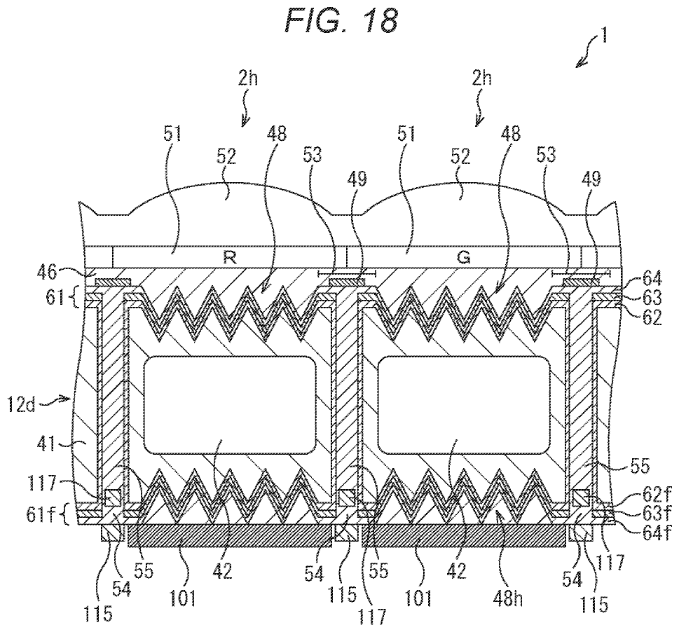

FIG. 18 is a cross-sectional diagram showing an example configuration in which charge retaining portions 117 are provided in the pixels 2h shown in FIG. 14. The charge retaining portions 117 are provided in the pixel separation portions 54. Wiring lines 115 for transferring electric charge from the photoelectric conversion regions to the charge retaining portions 117 are formed on the wiring layer side.

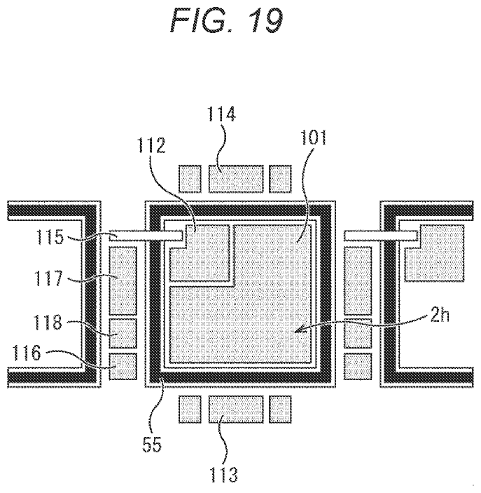

FIG. 19 is a plan view of the pixels 2h shown in FIG. 18 as viewed from the wiring layer side. The reflective films 101, transfer gates 112, reset gates 113, amplification transistors 114, wiring lines 115, FDs 116, the charge retaining portions 117, and FGs 118 are arranged on the surfaces on the wiring layer side of the pixels 2h shown in FIG. 19.

Like the pixels 2h shown in FIG. 17, the pixels 2h shown in FIG. 19 are of a two-pixel sharing type, and each reset gate 113 and each amplification transistor 114 are shared between two pixels. In the pixels 2h shown in FIG. 19, the reflective films 101 are formed so as to cover the photoelectric conversion regions.

The reflective films 101 are not formed in the regions in which the transfer gates 112 are formed. Electric charge is transferred from the photoelectric conversion regions to the charge retaining portions 117 via the transfer gates 112 and the wiring lines 115, and the electric charge stored in the charge retaining portions 117 is transferred to the FDs 116 via the FGs 118.

As the photoelectric conversion regions are surrounded by the pixel separation portions 54, leakage of light between pixels can be prevented, and thus, color mixing between pixels can be prevented. Further, as the reflective films 101 are formed on the wiring layer side of the photoelectric conversion regions, it is possible to prevent light from leaking to the wiring layer side.

As described above, the eighth embodiment can also be applied to pixels of a global shutter system. Further, pixels of a global shutter system, or a pixel structure including the charge retaining portions 117, can also be applied to the first to seventh embodiments, and the ninth and subsequent embodiments described below.

The first to eighth embodiments can also be applied to pixels having a structure in which a plurality of layers is stacked. For example, in the pixels 2h shown in FIG. 18, wiring layers (not shown) are stacked on the lower side of the reflective films 101. Further, on the lower side of the wiring layers, a support substrate may be stacked, a substrate having a memory formed therein may be stacked, or a substrate having a logic circuit formed therein may be stacked. The embodiments described above and the embodiments described below can be adopted, without being limited by the number and the structure of layers stacked on the wiring layer side.

### Ninth Embodiment

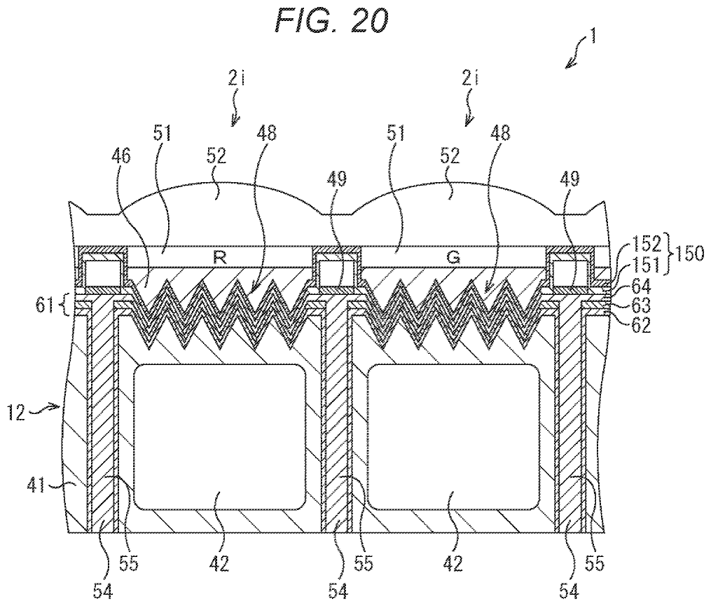

FIG. 20 shows the configuration of pixels 2i according to a ninth embodiment. The ninth embodiment can be combined with the pixels 2 according to any of the first to eighth embodiments. A case where the ninth embodiment is applied to the pixels 2a according to the first embodiment is now described as an example.

In the pixels 2i according to the ninth embodiment, waveguides that reflect light and guide light to the photoelectric conversion regions are formed on the light incident face side. FIG. 20 is a cross-sectional diagram showing an example configuration of the pixels 2i according to the ninth embodiment.

Waveguides 150 are formed in the color filter layers 51 of the pixels 2i shown in FIG. 20. The waveguides 150 are formed at the locations of the light blocking films 49, and each of the waveguides 150 is formed with a two-layer film of a film 151 and a film 152 that have protruding shapes in the drawing. The description of the waveguides formed with two layers will be continued below, but the number of layers may be other than two.

As the film 151 and the film 152, dielectric materials having a high refractive index, such as SiO2 (silicon dioxide), SiNx (silicon nitride), Al2O3 (aluminum oxide), TiO2 (titanium oxide), Ta2O3 (tantalum trioxide), and TiN (titanium nitride), can be used. Also, metals such as tungsten (W), silver (Ag), and aluminum (Al) can be used for the film 151 and the film 152. Alternatively, one of the film 151 and the film 152 may be formed with a material having a high refractive index, and the other one may be formed with a metal.

As the films of materials having different refractive indexes are stacked, the waveguides 150 function as films that reflect light. Alternatively, to have the function to reflect light, the waveguides 150 may be formed with metal films. In a case where metal films are used, the films are not formed in the recessed regions 48.

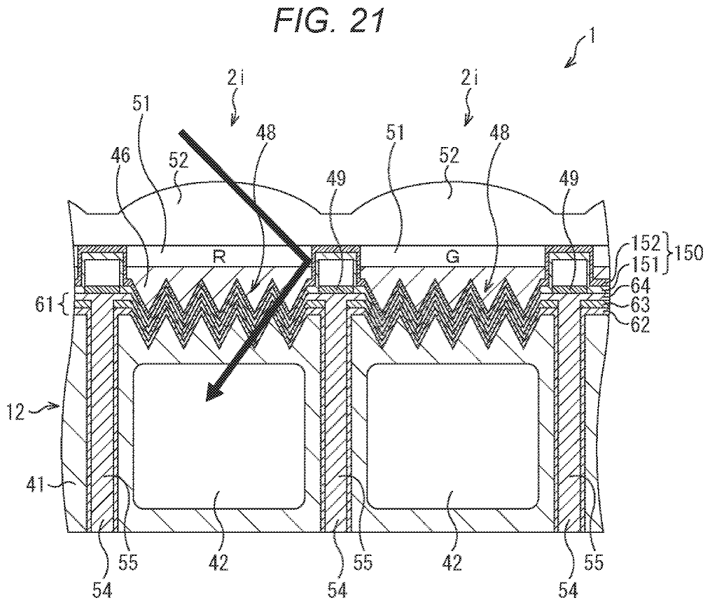

The waveguides 150 are formed in the color filter layers 51, so that color mixing in the adjacent pixels can be reduced. Referring now to FIG. 21, light that has entered the left-side pixel 2i from the left in the drawing is reflected by the waveguide 150, and then enters the N-type semiconductor region 42 of the left-side pixel 2i, as indicated by an arrow in FIG. 21.

In a case where the waveguides 150 are not formed, there is a possibility that light that has entered the left-side pixel 2i from the left in the drawing will enter the N-type semiconductor region 42 of the right-side pixel 2i, resulting in color mixing. However, because the waveguides 150 are formed, light is reflected by the waveguides 150 as described above, and does not enter any adjacent pixel. As the waveguides 150 are formed, color mixing in adjacent pixels can be reduced. Also, the amount of light that enters the photoelectric conversion regions can be increased, and thus, photoelectric conversion efficiency can be increased.

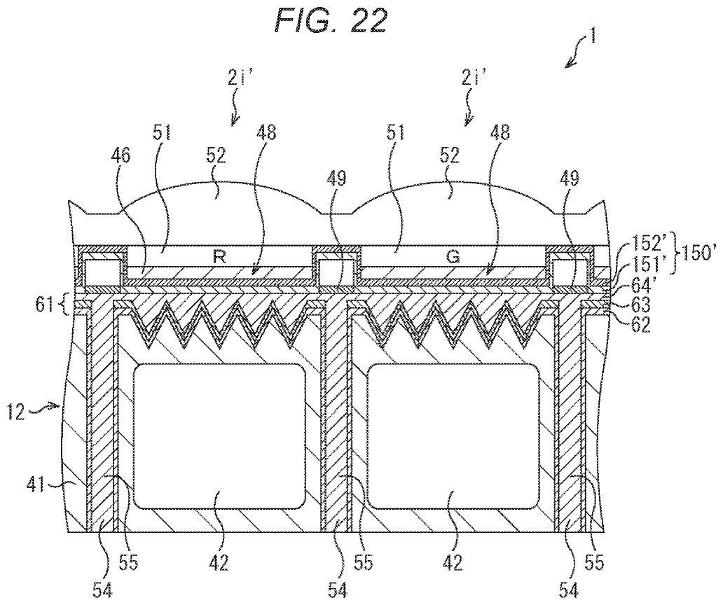

FIG. 22 is a cross-sectional diagram showing another configuration of the pixels 2i according to the ninth embodiment. Pixels 2i′ shown in FIG. 22 have the same configuration as the pixels 2i shown in FIG. 20, except that the recessed regions 48 are partially planarized.

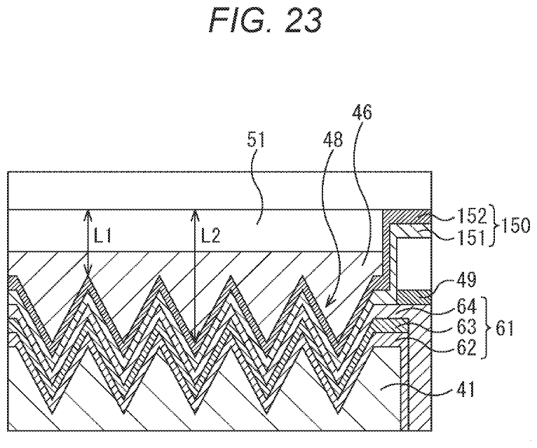

Referring now to FIG. 23, the reason why the upper portions of the recessed regions 48 are planarized is described.

FIG. 23 is an enlarged view of a recessed region 48 in the structure of the pixels 2i shown in FIG. 20. The recessed region 48 is formed with the hafnium oxide film 62, the aluminum oxide film 63, and the silicon oxide film 64, and is formed in a shape having irregularities. Further, in a case where the waveguides 150 are formed, the film 151 and the film 152 are also stacked in the recessed regions 48, and the film 151 and the film 152 are also formed in shapes having irregularities in the pixels 2i shown in FIG. 20.

The distance from the upper portion of the color filter layer 51 to the recessed region 48 (a recessed region 48 in which the film 151 and the film 152 are stacked) is now discussed. The recessed region 48 has peak portions and valley portions. The peak portions of the recessed region 48 are the portions of the recessed region 48 located at positions close to the color filter layer 51. Meanwhile, the valley portions of the recessed region 48 are the portions of the recessed region 48 located at positions far from the color filter layer 51.

The distance from the color filter layer 51 to a peak portion of the recessed region 48 is defined as a distance L1. On the other hand, the distance from the color filter layer 51 to a valley portion of the recessed region 48 is defined as a distance L2. In this case, the relationship between the distance L1 and the distance L2 is expressed as: distance L1<distance L2. There is a possibility that variation in sensitivity might be caused by variation in distance from the color filter layer 51 to the recessed region 48.

When light traveling through the distance L1 is compared with light traveling through the distance L2, the light traveling through the distance L2 is less likely to pass than the light traveling through the distance L1 due to the longer distance, and might not be efficiently transmitted. To correct such a structure in which portions that efficiently transmit light and portions that do not efficiently transmit light coexist, or a structure in which there is variation in sensitivity, the configuration shown in FIG. 22 is adopted, so that the distance L1 and the distance L2 can be regarded as equal.

Referring to FIG. 22, a silicon oxide film 64′ (denoted with a reference numeral accompanied by a prime mark to be distinguished from the silicon oxide film 64 in FIG. 20 and others) formed on the side closer to the color filter layers 51 among the three layers constituting the recessed regions 48 also fills the portions corresponding to the valleys of the recessed regions 48, and the silicon oxide film 64′ is planarized on the side of the color filter layers 51.

As the silicon oxide film 64′ is planarized, a film 151′ and a film 152′ stacked thereon are also planarized. As the sides of the recessed regions 48 closer to the color filter layers 51 are planarized in this manner, the distances corresponding to the distance L1 and the distance L2 can be made equal. Accordingly, it is possible to obtain a configuration in which variation in sensitivity is reduced, instead of a configuration in which sensitivity varies as described above.

As shown in FIG. 22, in a case where the silicon oxide film 64′ is planarized, the silicon oxide film 64′ is first formed by the atomic layer deposition (ALD) method. The silicon oxide film 64′ is then polished to be flat by chemical mechanical polishing (CMP), so that the flat silicon oxide film 64′ can be formed. Further, after the flat silicon oxide film 64′ is formed, the film 151′ and the film 152′ are formed, so that the waveguides 150 can be formed.

As the pixels 2 have a configuration including the waveguides 150 as described above, color mixing in the adjacent pixels can be reduced, and light can be guided into the photoelectric conversion regions, to increase the amount of light entering the photoelectric conversion regions.

### Tenth Embodiment

Referring again to FIG. 2, for example, the transparent insulating film 46 is formed between the color filter layers 51 and the recessed regions 48 in the first to ninth embodiments. A structure in which the transparent insulating film 46 is not formed can be adopted. Pixels 2 having a structure in which the transparent insulating film 46 is not formed are now described as pixels 2j according to a tenth embodiment.

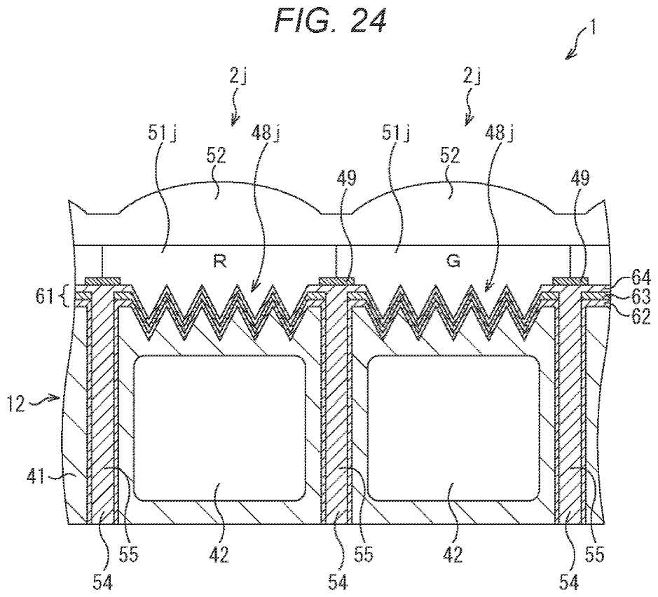

FIG. 24 is a cross-sectional diagram showing an example configuration of pixels 2j according to the tenth embodiment. The configuration of the pixels 2j shown in FIG. 24 is the same as the configuration of the pixels 2a according to the first embodiment shown in FIG. 2, except for excluding the transparent insulating film 46.

In the pixels 2j shown in FIG. 24, color filter layers 51j are formed on recessed regions 48j. Therefore, the lower portions of the color filter layers 51j have irregular shapes that match the shapes of the recessed regions 48. As in the pixels 2j shown in FIG. 24, the color filter layers 51j may be formed on the recessed regions 48j. With the pixels 2j having such a configuration, it is possible to achieve the effects of provision of the recessed regions 48j, such as an effect to increase photoelectric conversion efficiency in the photoelectric conversion regions, for example.

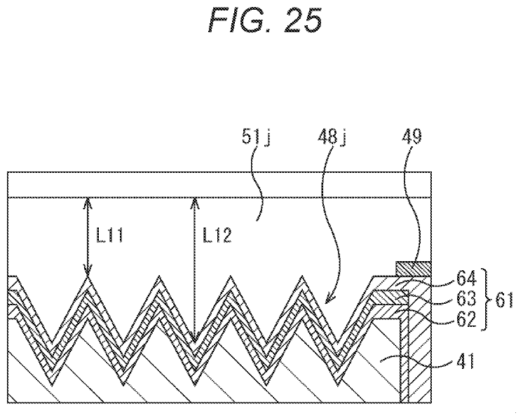

In the configuration of the pixels 2j shown in FIG. 24, there is a possibility that variation in sensitivity will occur. The possibility of the occurrence of variation in sensitivity is now described with reference to FIG. 25.

FIG. 25 is an enlarged view of a recessed region 48j in the structure of the pixels 2j shown in FIG. 24. The distance from the upper portion of the color filter layer 51j to the recessed region 48j is now discussed. The recessed region 48j has peak portions and valley portions. The peak portions of the recessed region 48j are the portions of the recessed region 48j located at positions close to the color filter layer 51j. Meanwhile, the valley portions of the recessed region 48j are the portions of the recessed region 48j located at positions far from the color filter layer 51j.

The distance from the color filter layer 51j to a peak portion of the recessed region 48j is defined as a distance L11. On the other hand, the distance from the color filter layer 51j to a valley portion of the recessed region 48j is defined as a distance L12. In this case, the relationship between the distance L11 and the distance L12 is expressed as: distance L11<distance L12. There is a possibility that variation in sensitivity might be caused by the variation in distance from the color filter layer 51j to the recessed region 48j.

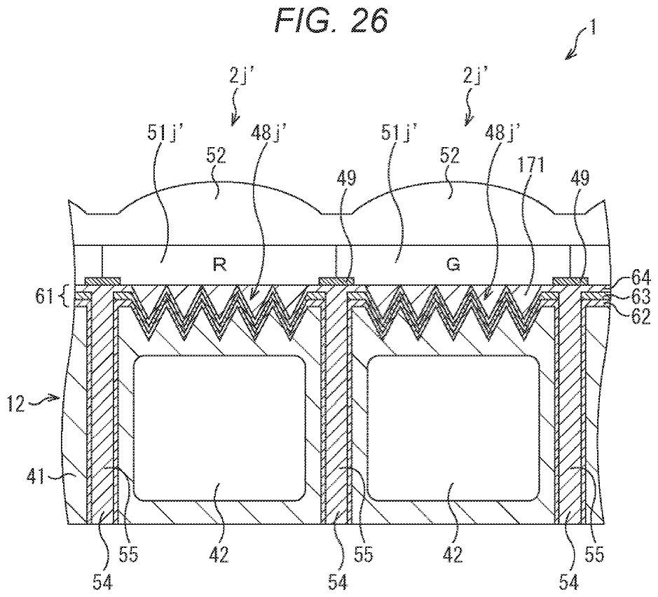

When light traveling through the distance L11 is compared with light traveling through the distance L12, the light traveling through the distance L12 is less likely to pass than the light traveling through the distance L11 due to the longer distance, and might not be efficiently transmitted. To correct such a structure in which portions that efficiently transmit light and portions that do not efficiently transmit light coexist, or a structure in which there is variation in sensitivity, the configuration shown in FIG. 26 may be adopted, so that the distance L11 and the distance L12 can be regarded as equal.

FIG. 26 is a cross-sectional diagram showing another example configuration of pixels 2j according to the tenth embodiment. Here, the pixels 2j′ are denoted by a reference numeral with a prime mark, to be distinguished from the pixels 2j shown in FIG. 24.

In the pixels 2j′ shown in FIG. 26, the portions corresponding to the valleys of recessed regions 48j′ are filled with a planarizing material 171. As the portions corresponding to the valleys of the recessed regions 48j′ are filled with the planarizing material 171, the upper portions of the recessed regions 48′ including the planarizing material 171 have a flat shape without irregularities. Accordingly, the lower side of color filter layers 51j′ also has a flat shape without irregularities.

The same material as the material of the transparent insulating film 46 can be used as the planarizing material 171, for example. The planarizing material 171 may be any material that has a small decrease in sensitivity.

As both the upper portions and the lower portions of the color filter layers 51′ are flat, the thickness of the color filter layers 51′ becomes uniform, and the occurrence of variation in sensitivity can be reduce.

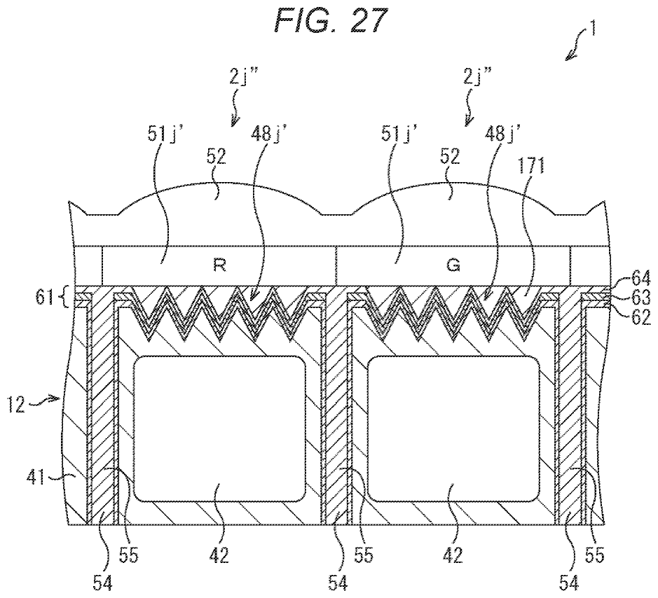

As another configuration of the pixels 2j, a configuration not including the light blocking films 49 may be adopted as shown in FIG. 27. Pixels 2j″ shown in FIG. 27 have the same configuration as the configuration of the pixels 2j′ shown in FIG. 26, except that the light blocking films 49 are removed.

The pixels 2j, the pixels 2j′, and the pixels 2j″ shown in FIGS. 24, 26, and 27 have been described as example cases where the tenth embodiment is applied to the pixels 2a according to the first embodiment, but the tenth embodiment can also be applied to any of the second to ninth embodiments.

### Eleventh Embodiment

The pixels 2 including the recessed regions 48 can also be applied to pixels that receive infrared (IR) light. Here, a case where pixels that receive light in the visible light range and pixels that receive infrared light are arranged in the pixel array unit 3 (FIG. 1) is described as an example. As pixels that receive light in the visible light range and pixels that receive infrared light are arranged in the pixel array unit 3, a color image and an infrared image can be acquired at the same time.

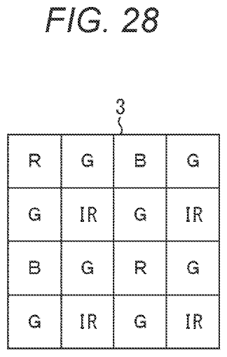

In a case where pixels that receive light in the visible light range and pixels that receive infrared light are arranged in the pixel array unit 3, red (R) pixels to be used for detecting the red color, green (G) pixels to be used for detecting the green color, blue (B) pixels to be used for detecting the blue color, and IR pixels to be used for detecting infrared light are arranged in a two-dimensional lattice fashion in the pixel array unit 3, as shown in FIG. 28.

FIG. 28 shows an example array of pixels 2 in the pixel array unit 3. The example shown in FIG. 28 is an example of a pixel array in which a pattern formed with 4×4 pixels is set as one unit, and the pixels 2 are arranged at the ratio of R pixels:G pixels:B pixels:IR pixels=2:8:2:4. More specifically, the G pixels are arranged in a checkered pattern. The R pixels are disposed in the first column of the first row and the third column in the third row. The B pixels are disposed in the third column of the first row and the first column of the third row. The IR pixels are disposed at the remaining pixel positions. Further, this pixel array pattern is repeatedly disposed in the row direction and the column direction in the pixel array unit 3.

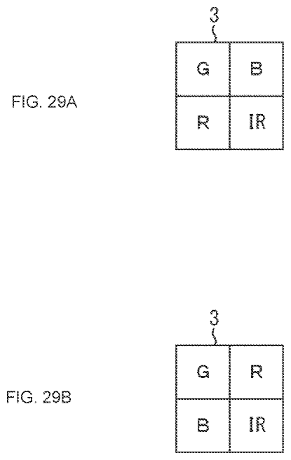

The pixel array shown in FIG. 28 is merely an example, and some other array can be adopted. For example, as shown in A of FIG. 29 and B of FIG. 29, the pixels 2 may be arranged at a ratio of R pixels:G pixels:B pixels:IR pixels=1:1:1:1 in each pattern, with one unit being a pattern formed with 2×2 pixels.

In the array shown in A of FIG. 28, a G pixel is disposed at the upper left, a B pixel is disposed at the upper right, an R pixel is disposed at the lower left, and an IR pixel is disposed at the lower right in the drawing. In the array shown in B of FIG. 28, a G pixel is disposed at the upper left, an R pixel is disposed at the upper right, a B pixel is disposed at the lower left, and an IR pixel is disposed at the lower right in the drawing.

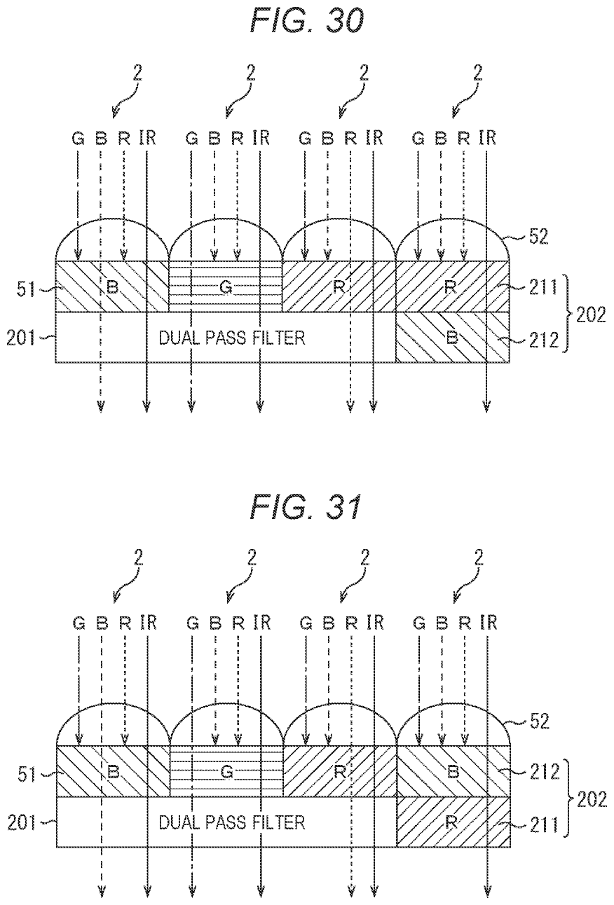

FIG. 30 schematically shows an example configuration of the filters of the respective pixels 2. In this example, a B pixel, a G pixel, an R pixel, and an IR pixel are arranged from left to right. In the R pixel, the G pixel, and the B pixel, on-chip lenses 52, color filter layers 51, and a dual pass filter 201 are stacked in this order from the light incident side.

In the color filter layers 51, a R filter that passes light in the wavelength bands of red and infrared light is provided for the R pixel, a G filter that passes light in the wavelength bands of green and infrared light is provided for the G pixel, and a B filter that passes light in the wavelength bands of blue and infrared light is provided for the B pixel. The dual pass filter 201 is a filter that has a transmission band for visible light and near-infrared light in a predetermined range.

In the IR pixel, an on-chip lens 52 and an IR filter 202 are stacked in this order from the light incident side. The IR filter 202 is formed by stacking a R filter 211 and a B filter 212. As the R filter 211 and the B filter 212 are stacked, the IR filter 202 (which is blue+red) that passes light beams having longer wavelengths than 800 nm is formed.

In the IR filter 202 shown in FIG. 30, the R filter 211 is disposed on the side of the on-chip lens 52, and the B filter 212 is disposed on the lower side. However, as shown in FIG. 31, the B filter 212 may be disposed on the side of the on-chip lens 52, and the R filter 211 may be disposed on the lower side.

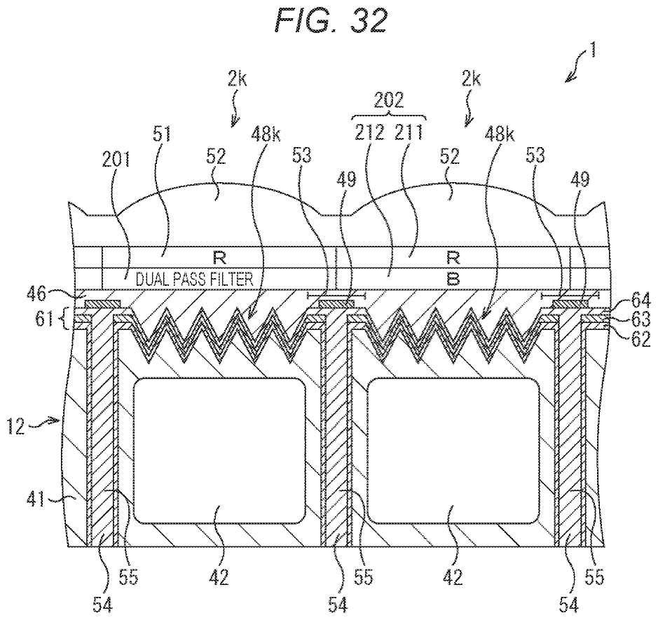

In a case where the pixels 2 having the recessed regions 48 are used in a solid-state imaging device 1 in which such R pixels, G pixels, B pixels, and IR pixels are disposed, a configuration as shown in FIG. 32 is obtained. FIG. 32 is a cross-sectional diagram showing the configuration of pixels 2k in a case where the configuration of the IR filter 202 shown in FIG. 30 is applied to the pixels 2a according to the first embodiment.

The pixels 2h shown in FIG. 32 represent an example in which an R pixel is disposed on the left side in the drawing, and an IR pixel is disposed on the right side in the drawing. Compared with the pixels 2a shown in FIG. 2, the R pixel has a configuration in which the dual pass filter 201 is added between the color filter layer 51 and the transparent insulating film 46. On the other hand, the IR pixel has a configuration in which a B filter 212 is added to an R filter 211 corresponding to the color filter layer 51.

As described above, the addition of the dual pass filter 201 or the B filter 212 might lower sensitivity. However, as recessed regions 48k are formed, the lowered sensitivity can be compensated, and the sensitivity can be further increased. Also, as the pixel separation portions 54 are provided, the light diffracted in the recessed regions 48k can be prevented from leaking into the adjacent pixels, and thus, color mixing can be reduced.

Although a case where the pixels 2a of the first embodiment and the eleventh embodiment are combined has been described as an example with reference to FIG. 32, the eleventh embodiment can be combined with any of the pixels 2b to 2j of the second to tenth embodiments.

### Twelfth Embodiment

The pixels 2a to 2k described as the first to eleventh embodiments include the recessed regions 48. The recessed regions 48 have a shape with irregularities. As the recessed regions 48 formed in a shape having irregularities are provided, incident light is scattered, and more light can be condensed than with pixels not including the recessed regions 48.

That is, as the recessed regions 48 are provided, photoelectric conversion capacity can be increased. Although the number of irregularities in the recessed regions 48 have not been specifically described in the above embodiments, it is possible to control sensitivity by adjusting the number of irregularities in the recessed regions 48.

Here, in a case where the portions of the recessed regions 48 located at positions far from the color filter layers 51 are referred as valley portions, sensitivity can be controlled by the number of the valley portions. It is considered that, when the number of the valley portions is large, scattering is likely to occur, and sensitivity becomes higher. Therefore, the number of the valley portions may be made to vary among the recessed regions 48, so that differences in sensitivity among the colors can be absorbed, and sensitivity can be adjusted to be uniform.

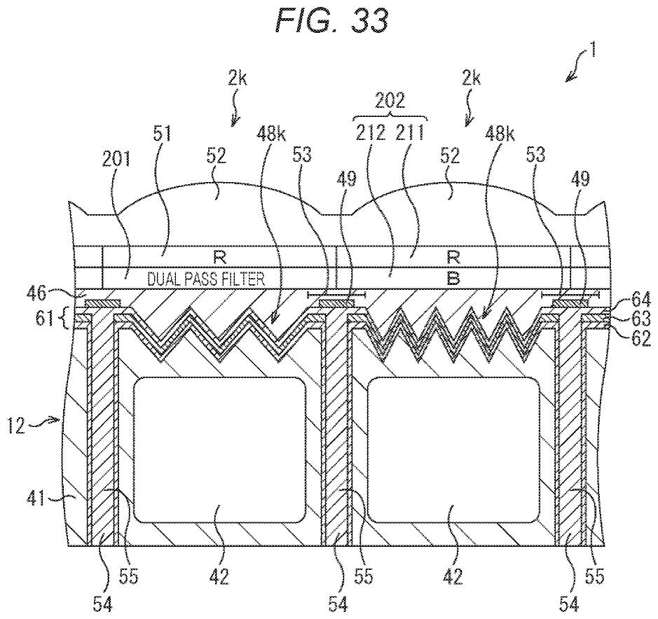

Here, a case where sensitivity is controlled by adjustment of the numbers of the valleys in the recessed regions 48 is described, with the pixels 2k according to the eleventh embodiment being taken as an example. FIG. 33 shows the pixels 2k shown in FIG. 32, but the number of the valleys in the recessed region 48k of the R pixel differs from the number of the valleys in the recessed region 48k of the IR pixel. In the example shown in FIG. 33, the number of the valleys in the recessed region 48k of the R pixel is three, and the number of the valleys in the recessed region 48k of the IR pixel is five.

In a case where the sensitivity of the IR pixel is likely to be lower than the sensitivity of the R pixel when the sensitivity of the R pixel is compared with the sensitivity of the IR pixel, the number of the valleys in the recessed region 48k of the IR pixel is made larger than the number of the valleys in the recessed region 48k of the R pixel, as shown in FIG. 33.

With this configuration, the increase caused in sensitivity by the formation of the recessed region 48k can be made larger in the IR pixel than in the R pixel. Accordingly, even if the sensitivity of the IR pixel becomes lower than that of the R pixel, the decrease can be compensated with the increase caused in sensitivity by the formation of the recessed region 48k. Thus, variation in sensitivity between the R pixel and the IR pixel can be reduced.

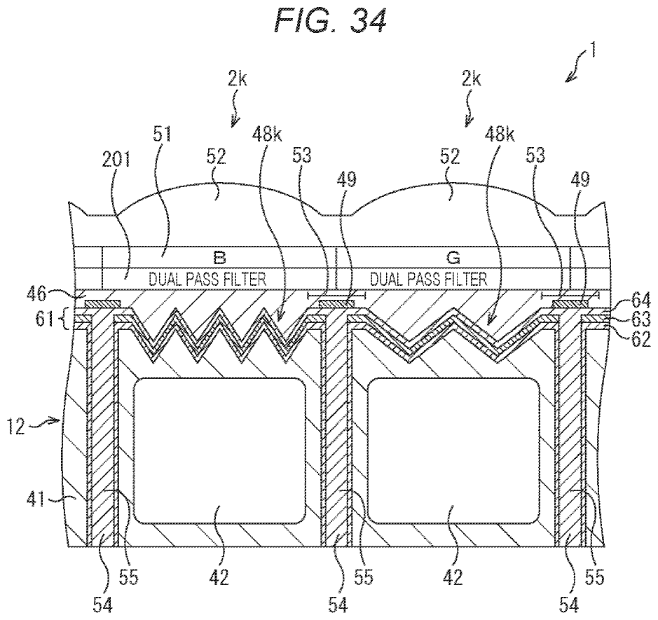

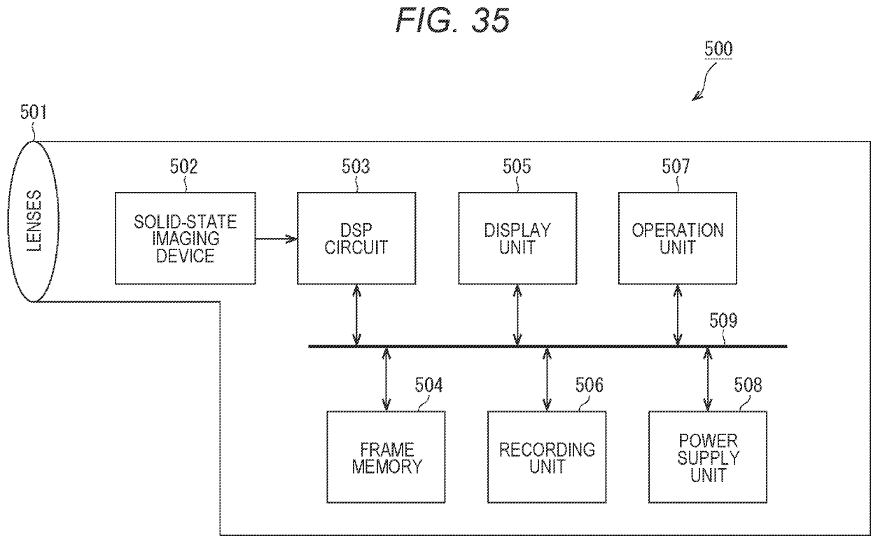

Likewise, a case with a G pixel and a B pixel is described with reference to FIG. 34. In the example shown in FIG. 34, the number of the valleys in the recessed region 48k of the G pixel shown on the right side is two, and the number of the valleys in the recessed region 48k of the B pixel shown on the left side is four. In a case where the sensitivity of the G pixel is likely to be higher than the sensitivity of the B pixel when the sensitivity of the B pixel is compared with the sensitivity of the G pixel, the number of the valleys in the recessed region 48k of the G pixel is made smaller than the number of the valleys in the recessed region 48k of the B pixel, as shown in FIG. 34.

With this configuration, the increase caused in sensitivity by the formation of the recessed region 48k can be made larger in the B pixel than in the G pixel. Accordingly, even if the sensitivity of the B pixel becomes lower than that of the G pixel, the decrease can be compensated with the increase caused in sensitivity by the formation of the recessed region 48k. Thus, variation in sensitivity between the B pixel and the G pixel can be reduced.

The examples shown in FIGS. 33 and 34 are cases where the sensitivity varies as follows: G pixel>R pixel>B pixel>IR pixel. Accordingly, the number of the valleys in the recessed region 48k varies as follows in these examples: IR pixel (5)>B pixel (4)>R pixel (3)>G pixel (2). Such an order of sensitivity and such an order of the number of the valleys in the recessed region 48 are merely examples, and do not indicate any restrictions.

Such a structure in which the number of the valleys in the recessed region 48 varies (twelfth embodiment) can be combined with any of the pixels 2a to 2k according to the first to eleventh embodiments.

<Example Applications to Electronic Apparatuses>

The technology of the present disclosure is not necessarily applied to a solid-state imaging device. Specifically, the technology of the present disclosure can be applied to any electronic apparatus using a solid-state imaging device as an image capturing unit (a photoelectric conversion portion), such as an imaging apparatus like a digital still camera or a video camera, a mobile terminal device having an imaging function, or a copying machine using a solid-state imaging device as the image reader. A solid-state imaging device may be in the form of a single chip, or may be in the form of a module that is formed by packaging an imaging unit and a signal processing unit or an optical system, and has an imaging function.

FIG. 35 is a block diagram showing an example configuration of an imaging apparatus as an electronic apparatus according to the present disclosure.

An imaging apparatus 500 shown in FIG. 35 includes an optical unit 501 formed with lenses and the like, a solid-state imaging device (an imaging device) 502 that adopts the configuration of the solid-state imaging device 1 shown in FIG. 1, and a digital signal processor (DSP) circuit 503 that is a camera signal processing circuit. The imaging apparatus 500 also includes a frame memory 504, a display unit 505, a recording unit 506, an operation unit 507, and a power supply unit 508. The DSP circuit 503, the frame memory 504, the display unit 505, the recording unit 506, the operation unit 507, and the power supply unit 508 are connected to one another via a bus line 509.

The optical unit 501 gathers incident light (image light) from an object, and forms an image on the imaging surface of the solid-state imaging device 502. The solid-state imaging device 502 converts the amount of the incident light, which has been gathered as the image on the imaging surface by the optical unit 501, into an electrical signal for each pixel, and outputs the electrical signal as a pixel signal. The solid-state imaging device 1 in FIG. 1, which is a solid-state imaging device that has an increased sensitivity while reducing color mixing degradation, can be used as the solid-state imaging device 502.

The display unit 505 is formed with a panel display device such as a liquid crystal panel or an organic electro-luminescence (EL) panel, for example, and displays a moving image or a still image formed by the solid-state imaging device 502. The recording unit 506 records the moving image or the still image formed by the solid-state imaging device 502 on a recording medium such as a hard disk or a semiconductor memory.

When operated by a user, the operation unit 507 issues operating instructions as to various functions of the imaging apparatus 500. The power supply unit 508 supplies various power sources as the operation power sources for the DSP circuit 503, the frame memory 504, the display unit 505, the recording unit 506, and the operation unit 507, as appropriate.

As described above, the solid-state imaging device 1 described above is used as the solid-state imaging device 502, so that sensitivity can be increased while color mixing degradation is reduced. Accordingly, the quality of captured images can also be increased in the imaging apparatus 500, which is a video camera, a digital still camera, a cameral module for mobile devices such as portable telephone devices, or the like.

Embodiments of the present disclosure are not limited to the above described embodiments, and various modifications may be made to them without departing from the scope of the present disclosure.

In the solid-state imaging devices in the above described examples, the first conductivity type is the P-type, the second conductivity type is the N-type, and electrons are used as signal charges. However, the present disclosure can also be applied to solid-state imaging devices in which holes are used as signal charges. That is, the first conductivity type can be the N-type, the second conductivity type can be the P-type, and the conductivity types of the above described respective semiconductor regions can be reversed.

The technology of the present disclosure can also be applied not only to solid-state imaging devices that sense an incident light quantity distribution of visible light and form an image in accordance with the distribution, but also to solid-state imaging devices (physical quantity distribution sensors) in general, such as a solid-state imaging device that senses an incident quantity distribution of infrared rays, X-rays, particles, or the like, and forms an image in accordance with the distribution, or a fingerprint sensor that senses a distribution of some other physical quantity in a broad sense, such as pressure or capacitance, and forms an image in accordance with the distribution.

<Example Application to an Endoscopic Surgery System>

The technology (the present technology) according to the present disclosure can be applied to various products. For example, the technology according to the present disclosure may be applied to an endoscopic surgery system.

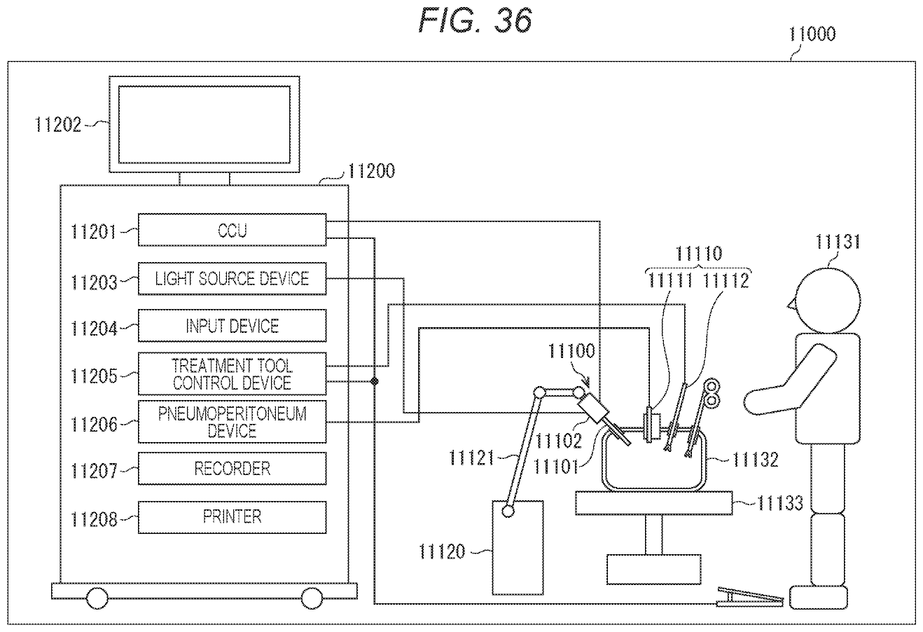

FIG. 36 is a diagram schematically showing an example configuration of an endoscopic surgery system to which the technology (the present technology) according to the present disclosure can be applied.

FIG. 36 shows a situation where a surgeon (a physician) 11131 is performing surgery on a patient 11132 on a patient bed 11133, using an endoscopic surgery system 11000. As shown in the drawing, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various kinds of devices for endoscopic surgery are mounted.

The endoscope 11100 includes a lens barrel 11101 that has a region of a predetermined length from the top end to be inserted into a body cavity of the patient 11132, and a camera head 11102 connected to the base end of the lens barrel 11101. In the example shown in the drawing, the endoscope 11100 is designed as a so-called rigid scope having a rigid lens barrel 11101. However, the endoscope 11100 may be designed as a so-called flexible scope having a flexible lens barrel.

At the top end of the lens barrel 11101, an opening into which an objective lens is inserted is provided. A light source device 11203 is connected to the endoscope 11100, and the light generated by the light source device 11203 is guided to the top end of the lens barrel by a light guide extending inside the lens barrel 11101, and is emitted toward the current observation target in the body cavity of the patient 11132 via the objective lens. Note that the endoscope 11100 may be a forward-viewing endoscope, an oblique-viewing endoscope, or a side-viewing endoscope.

An optical system and an imaging device are provided inside the camera head 11102, and reflected light (observation light) from the current observation target is converged on the imaging device by the optical system. The observation light is photoelectrically converted by the imaging device, and an electrical signal corresponding to the observation light, or an image signal corresponding to the observation image, is generated. The image signal is transmitted as RAW data to a camera control unit (CCU) 11201.

The CCU 11201 is formed with a central processing unit (CPU), a graphics processing unit (GPU), or the like, and collectively controls operations of the endoscope 11100 and a display device 11202. Further, the CCU 11201 receives an image signal from the camera head 11102, and subjects the image signal to various kinds of image processing, such as a development process (a demosaicing process), for example, to display an image based on the image signal.

Under the control of the CCU 11201, the display device 11202 displays an image based on the image signal subjected to the image processing by the CCU 11201.

The light source device 11203 is formed with a light source such as a light emitting diode (LED), for example, and supplies the endoscope 11100 with illuminating light for imaging the surgical site or the like.

An input device 11204 is an input interface to the endoscopic surgery system 11000. The user can input various kinds of information and instructions to the endoscopic surgery system 11000 via the input device 11204. For example, the user inputs an instruction or the like to change imaging conditions (such as the type of illuminating light, the magnification, and the focal length) for the endoscope 11100.

A treatment tool control device 11205 controls driving of the energy treatment tool 11112 for tissue cauterization, incision, blood vessel sealing, or the like. A pneumoperitoneum device 11206 injects a gas into a body cavity of the patient 11132 via the pneumoperitoneum tube 11111 to inflate the body cavity, for the purpose of securing the field of view of the endoscope 11100 and the working space of the surgeon. A recorder 11207 is a device capable of recording various kinds of information about the surgery. A printer 11208 is a device capable of printing various kinds of information relating to the surgery in various formats such as text, images, graphics, and the like.

Note that the light source device 11203 that supplies the endoscope 11100 with the illuminating light for imaging the surgical site can be formed with an LED, a laser light source, or a white light source that is a combination of an LED and a laser light source, for example. In a case where a white light source is formed with a combination of RGB laser light sources, the output intensity and the output timing of each color (each wavelength) can be controlled with high precision. Accordingly, the white balance of an image captured by the light source device 11203 can be adjusted. Alternatively, in this case, laser light from each of the RGB laser light sources may be emitted onto the current observation target in a time-division manner, and driving of the imaging device of the camera head 11102 may be controlled in synchronization with the timing of the light emission. Thus, images corresponding to the respective RGB colors can be captured in a time-division manner. According to the method, a color image can be obtained without any color filter provided in the imaging device.

Further, the driving of the light source device 11203 may also be controlled so that the intensity of light to be output is changed at predetermined time intervals. The driving of the imaging device of the camera head 11102 is controlled in synchronism with the timing of the change in the intensity of the light, and images are acquired in a time-division manner and are then combined. Thus, a high dynamic range image with no black portions and no white spots can be generated.

Further, the light source device 11203 may also be designed to be capable of supplying light of a predetermined wavelength band compatible with special light observation. In special light observation, light of a narrower band than the illuminating light (or white light) at the time of normal observation is emitted, with the wavelength dependence of light absorption in body tissue being taken advantage of, for example. As a result, so-called narrow band light observation (narrow band imaging) is performed to image predetermined tissue such as a blood vessel in a mucosal surface layer or the like, with high contrast. Alternatively, in the special light observation, fluorescence observation for obtaining an image with fluorescence generated through emission of excitation light may be performed. In fluorescence observation, excitation light is emitted to body tissue so that the fluorescence from the body tissue can be observed (autofluorescence observation). Alternatively, a reagent such as indocyanine green (ICG) is locally injected into body tissue, and excitation light corresponding to the fluorescence wavelength of the reagent is emitted to the body tissue so that a fluorescent image can be obtained, for example. The light source device 11203 can be designed to be capable of supplying narrow band light and/or excitation light compatible with such special light observation.

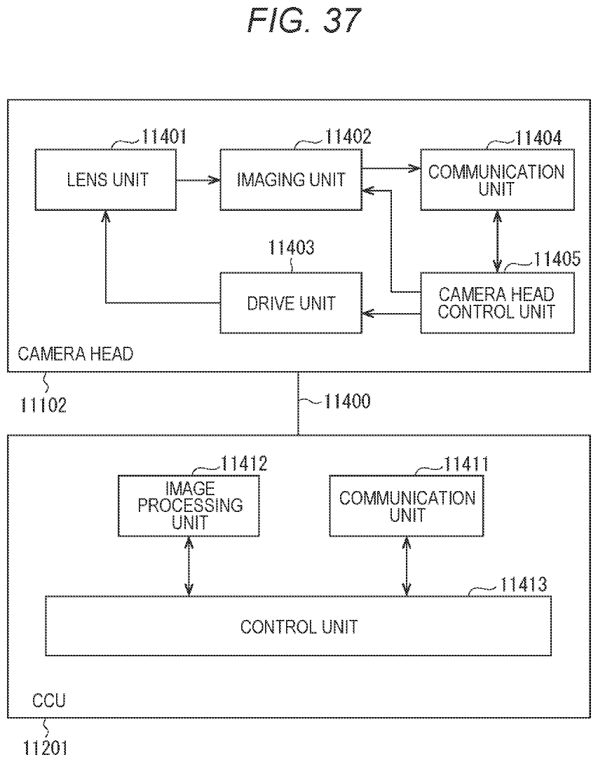

FIG. 37 is a block diagram showing an example of the functional configurations of the camera head 11102 and the CCU 11201 shown in FIG. 36.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at the connecting portion with the lens barrel 11101. Observation light captured from the top end of the lens barrel 11101 is guided to the camera head 11102, and enters the lens unit 11401. The lens unit 11401 is formed with a combination of a plurality of lenses including a zoom lens and a focus lens.

The imaging unit 11402 may be formed with one imaging device (a so-called single-plate type), or may be formed with a plurality of imaging devices (a so-called multiple-plate type). In a case where the imaging unit 11402 is of a multiple-plate type, for example, image signals corresponding to the respective RGB colors may be generated by the respective imaging devices, and be then combined to obtain a color image. Alternatively, the imaging unit 11402 may be designed to include a pair of imaging devices for acquiring right-eye and left-eye image signals compatible with three-dimensional (3D) display. As the 3D display is conducted, the surgeon 11131 can grasp more accurately the depth of the body tissue at the surgical site. Note that, in a case where the imaging unit 11402 is of a multiple-plate type, a plurality of lens units 11401 is provided for the respective imaging devices.

Further, the imaging unit 11402 is not necessarily provided in the camera head 11102. For example, the imaging unit 11402 may be provided immediately behind the objective lens in the lens barrel 11101.

The drive unit 11403 is formed with an actuator, and, under the control of the camera head control unit 11405, moves the zoom lens and the focus lens of the lens unit 11401 by a predetermined distance along the optical axis. With this arrangement, the magnification and the focal point of the image captured by the imaging unit 11402 can be adjusted as appropriate.

The communication unit 11404 is formed with a communication device for transmitting and receiving various kinds of information to and from the CCU 11201. The communication unit 11404 transmits the image signal obtained as RAW data from the imaging unit 11402 to the CCU 11201 via the transmission cable 11400.

The communication unit 11404 also receives a control signal for controlling the driving of the camera head 11102 from the CCU 11201, and supplies the control signal to the camera head control unit 11405. The control signal includes information about imaging conditions, such as information for specifying the frame rate of captured images, information for specifying the exposure value at the time of imaging, and/or information for specifying the magnification and the focal point of captured images, for example.

Note that the above imaging conditions such as the frame rate, the exposure value, the magnification, and the focal point may be appropriately specified by the user, or may be automatically set by the control unit 11413 of the CCU 11201 on the basis of an acquired image signal. In the latter case, the endoscope 11100 has a so-called auto-exposure (AE) function, an auto-focus (AF) function, and an auto-white-balance (AWB) function.

The camera head control unit 11405 controls the driving of the camera head 11102, on the basis of a control signal received from the CCU 11201 via the communication unit 11404.

The communication unit 11411 is formed with a communication device for transmitting and receiving various kinds of information to and from the camera head 11102. The communication unit 11411 receives an image signal transmitted from the camera head 11102 via the transmission cable 11400.

Further, the communication unit 11411 also transmits a control signal for controlling the driving of the camera head 11102, to the camera head 11102. The image signal and the control signal can be transmitted through electrical communication, optical communication, or the like.

The image processing unit 11412 performs various kinds of image processing on an image signal that is RAW data transmitted from the camera head 11102.

The control unit 11413 performs various kinds of control relating to display of an image of the surgical portion or the like captured by the endoscope 11100, and a captured image obtained through imaging of the surgical site or the like. For example, the control unit 11413 generates a control signal for controlling the driving of the camera head 11102.

Further, the control unit 11413 also causes the display device 11202 to display a captured image showing the surgical site or the like, on the basis of the image signal subjected to the image processing by the image processing unit 11412. In doing so, the control unit 11413 may recognize the respective objects shown in the captured image, using various image recognition techniques. For example, the control unit 11413 can detect the shape, the color, and the like of the edges of an object shown in the captured image, to recognize the surgical tool such as forceps, a specific body site, bleeding, the mist at the time of use of the energy treatment tool 11112, and the like. When causing the display device 11202 to display the captured image, the control unit 11413 may cause the display device 11202 to superimpose various kinds of surgery aid information on the image of the surgical site on the display, using the recognition result. As the surgery aid information is superimposed and displayed, and thus, is presented to the surgeon 11131, it becomes possible to reduce the burden on the surgeon 11131, and enable the surgeon 11131 to proceed with the surgery in a reliable manner.

The transmission cable 11400 connecting the camera head 11102 and the CCU 11201 is an electrical signal cable compatible with electric signal communication, an optical fiber compatible with optical communication, or a composite cable thereof.

Here, in the example shown in the drawing, communication is performed in a wired manner using the transmission cable 11400. However, communication between the camera head 11102 and the CCU 11201 may be performed in a wireless manner.

<Example Applications to Mobile Structures>

The technology (the present technology) according to the present disclosure can be applied to various products. For example, the technology according to the present disclosure may be embodied as a device mounted on any type of mobile structure, such as an automobile, an electrical vehicle, a hybrid electrical vehicle, a motorcycle, a bicycle, a personal mobility device, an airplane, a drone, a vessel, or a robot.

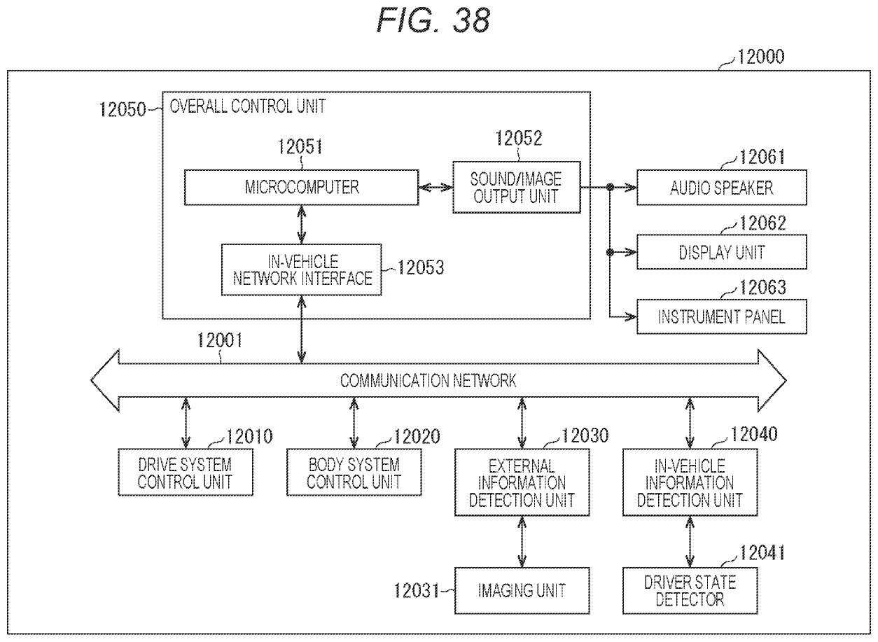

FIG. 38 is a block diagram schematically showing an example configuration of a vehicle control system that is an example of a mobile structure control system to which the technology according to the present disclosure may be applied.

A vehicle control system 12000 includes a plurality of electronic control units connected via a communication network 12001. In the example shown in FIG. 38, the vehicle control system 12000 includes a drive system control unit 12010, a body system control unit 12020, an external information detection unit 12030, an in-vehicle information detection unit 12040, and an overall control unit 12050. Further, a microcomputer 12051, a sound/image output unit 12052, and an in-vehicle network interface (I/F) 12053 are also shown as the functional components of the overall control unit 12050.

The drive system control unit 12010 controls operations of the devices related to the drive system of the vehicle according to various programs. For example, the drive system control unit 12010 functions as control devices such as a driving force generation device for generating a driving force of the vehicle such as an internal combustion engine or a driving motor, a driving force transmission mechanism for transmitting the driving force to the wheels, a steering mechanism for adjusting the steering angle of the vehicle, and a braking device for generating a braking force of the vehicle.

The body system control unit 12020 controls operations of the various devices mounted on the vehicle body according to various programs. For example, the body system control unit 12020 functions as a keyless entry system, a smart key system, a power window device, or a control device for various lamps such as a headlamp, a backup lamp, a brake lamp, a turn signal lamp, a fog lamp, or the like. In this case, the body system control unit 12020 can receive radio waves transmitted from a portable device that substitutes for a key, or signals from various switches. The body system control unit 12020 receives inputs of these radio waves or signals, and controls the door lock device, the power window device, the lamps, and the like of the vehicle.

The external information detection unit 12030 detects information outside the vehicle equipped with the vehicle control system 12000. For example, an imaging unit 12031 is connected to the external information detection unit 12030. The external information detection unit 12030 causes the imaging unit 12031 to capture an image of the outside of the vehicle, and receives the captured image. On the basis of the received image, the external information detection unit 12030 may perform an object detection process for detecting a person, a vehicle, an obstacle, a sign, characters on the road surface, or the like, or perform a distance detection process.

The imaging unit 12031 is an optical sensor that receives light, and outputs an electrical signal corresponding to the amount of received light. The imaging unit 12031 can output an electrical signal as an image, or output an electrical signal as distance measurement information. Further, the light to be received by the imaging unit 12031 may be visible light, or may be invisible light such as infrared rays.

The in-vehicle information detection unit 12040 detects information about the inside of the vehicle. For example, a driver state detector 12041 that detects the state of the driver is connected to the in-vehicle information detection unit 12040. The driver state detector 12041 includes a camera that captures an image of the driver, for example, and, on the basis of detected information input from the driver state detector 12041, the in-vehicle information detection unit 12040 may calculate the degree of fatigue or the degree of concentration of the driver, or determine whether or not the driver is dozing off.

On the basis of the external/internal information acquired by the external information detection unit 12030 or the in-vehicle information detection unit 12040, the microcomputer 12051 can calculate the control target value of the driving force generation device, the steering mechanism, or the braking device, and output a control command to the drive system control unit 12010. For example, the microcomputer 12051 can perform cooperative control to achieve the functions of an advanced driver assistance system (ADAS), including vehicle collision avoidance or impact mitigation, follow-up running based on the distance between vehicles, vehicle velocity maintenance running, vehicle collision warning, vehicle lane deviation warning, or the like.

Further, the microcomputer 12051 can also perform cooperative control to conduct automatic driving or the like for autonomously running not depending on the operation of the driver, by controlling the driving force generation device, the steering mechanism, the braking device, or the like on the basis of information about the surroundings of the vehicle, the information having being acquired by the external information detection unit 12030 or the in-vehicle information detection unit 12040.

The microcomputer 12051 can also output a control command to the body system control unit 12030, on the basis of the external information acquired by the external information detection unit 12030. For example, the microcomputer 12051 controls the headlamp in accordance with the position of the leading vehicle or the oncoming vehicle detected by the external information detection unit 12030, and performs cooperative control to achieve an anti-glare effect by switching from a high beam to a low beam, or the like.

The sound/image output unit 12052 transmits an audio output signal and/or an image output signal to an output device that is capable of visually or audibly notifying the passenger(s) of the vehicle or the outside of the vehicle of information. In the example shown in FIG. 38, an audio speaker 12061, a display unit 12062, and an instrument panel 12063 are shown as output devices. The display unit 12062 may include an on-board display and/or a head-up display, for example.

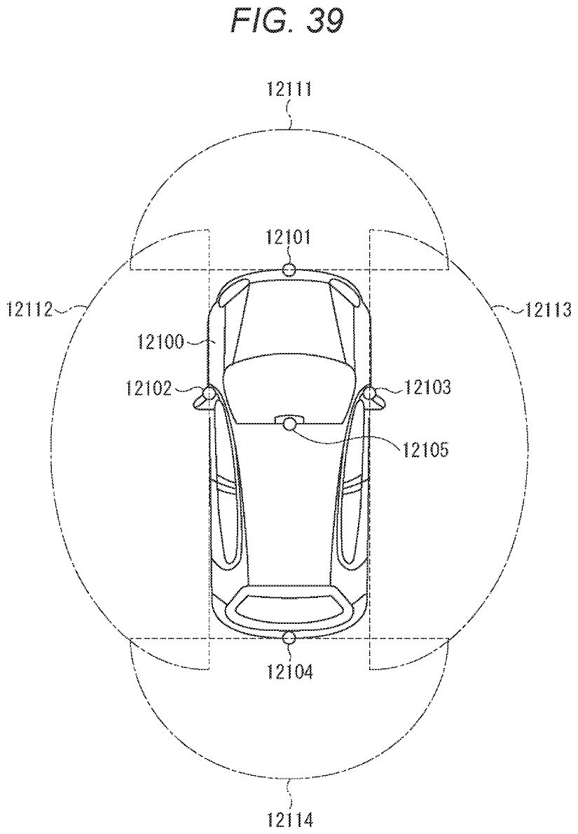

FIG. 39 is a diagram showing an example of installation positions of imaging units 12031.

In FIG. 39, imaging units 12101, 12102, 12103, 12104, and 12105 are included as the imaging units 12031.

Imaging units 12101, 12102, 12103, 12104, and 12105 are provided at the following positions: the front end edge of a vehicle 12100, a side mirror, the rear bumper, a rear door, an upper portion of the front windshield inside the vehicle, and the like, for example. The imaging unit 12101 provided on the front end edge and the imaging unit 12105 provided on the upper portion of the front windshield inside the vehicle mainly capture images ahead of the vehicle 12100. The imaging units 12102 and 12103 provided on the side mirrors mainly capture images on the sides of the vehicle 12100. The imaging unit 12104 provided on the rear bumper or a rear door mainly captures images behind the vehicle 12100. The imaging unit 12105 provided on the upper portion of the front windshield inside the vehicle is mainly used for detection of a vehicle running in front of the vehicle, a pedestrian, an obstacle, a traffic signal, a traffic sign, a lane, or the like.

Note that FIG. 39 shows an example of the imaging ranges of the imaging units 12101 to 12104. An imaging range 12111 indicates the imaging range of the imaging unit 12101 provided on the front end edge, imaging ranges 12112 and 12113 indicate the imaging ranges of the imaging units 12102 and 12103 provided on the respective side mirrors, and an imaging range 12114 indicates the imaging range of the imaging unit 12104 provided on the rear bumper or a rear door. For example, image data captured by the imaging units 12101 to 12104 are superimposed on one another, so that an overhead image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging devices, or may be an imaging device having pixels for phase difference detection.

For example, on the basis of distance information obtained from the imaging units 12101 to 12104, the microcomputer 12051 calculates the distances to the respective three-dimensional objects within the imaging ranges 12111 to 12114, and temporal changes in the distances (the velocities relative to the vehicle 12100). In this manner, the three-dimensional object that is the closest three-dimensional object on the traveling path of the vehicle 12100 and is traveling at a predetermined velocity (0 km/h or higher, for example) in substantially the same direction as the vehicle 12100 can be extracted as the vehicle running in front of the vehicle 12100. Further, the microcomputer 12051 can set beforehand an inter-vehicle distance to be maintained in front of the vehicle running in front of the vehicle 12100, and can perform automatic brake control (including follow-up stop control), automatic acceleration control (including follow-up start control), and the like. In this manner, it is possible to perform cooperative control to conduct automatic driving or the like to autonomously travel not depending on the operation of the driver.

For example, in accordance with the distance information obtained from the imaging units 12101 to 12104, the microcomputer 12051 can extract three-dimensional object data concerning three-dimensional objects under the categories of two-wheeled vehicles, regular vehicles, large vehicles, pedestrians, utility poles, and the like, and use the three-dimensional object data in automatically avoiding obstacles. For example, the microcomputer 12051 classifies the obstacles in the vicinity of the vehicle 12100 into obstacles visible to the driver of the vehicle 12100 and obstacles difficult to visually recognize. The microcomputer 12051 then determines collision risks indicating the risks of collision with the respective obstacles. If a collision risk is equal to or higher than a set value, and there is a possibility of collision, the microcomputer 12051 can output a warning to the driver via the audio speaker 12061 and the display unit 12062, or can perform driving support for avoiding collision by performing forced deceleration or avoiding steering via the drive system control unit 12010.

At least one of the imaging units 12101 to 12104 may be an infrared camera that detects infrared rays. For example, the microcomputer 12051 can recognize a pedestrian by determining whether or not a pedestrian exists in images captured by the imaging units 12101 to 12104. Such pedestrian recognition is carried out through a process of extracting feature points from the images captured by the imaging units 12101 to 12104 serving as infrared cameras, and a process of performing a pattern matching on the series of feature points indicating the outlines of objects and determining whether or not there is a pedestrian, for example. If the microcomputer 12051 determines that a pedestrian exists in the images captured by the imaging units 12101 to 12104, and recognizes a pedestrian, the sound/image output unit 12052 controls the display unit 12062 to display a rectangular contour line for emphasizing the recognized pedestrian in a superimposed manner. Further, the sound/image output unit 12052 may also control the display unit 12062 to display an icon or the like indicating the pedestrian at a desired position.

In this specification, a system means an entire apparatus formed with a plurality of devices.

Note that the advantageous effects described in this specification are merely examples, and the advantageous effects of the present technology are not limited to them or may include other effects.

Note that embodiments of the present technology are not limited to the above described embodiments, and various modifications may be made to them without departing from the scope of the present technology.

Note that the present technology may also be embodied in the configurations described below.

(1)

A solid-state imaging device including:

a substrate;

a plurality of photoelectric conversion regions formed in the substrate;

a trench that is formed between the photoelectric conversion regions, and penetrates the substrate; and

a recessed region that includes a plurality of concave portions, and is provided above the photoelectric conversion regions and on a side of a light receiving surface of the substrate,

in which the substrate includes a III-V semiconductor or polycrystalline SiXGe (1-x) (x=0 to 1).

(2)

The solid-state imaging device according to (1), in which

the III-V semiconductor includes one of indium phosphide (InP), indium arsenide (InAs), indium arsenide phosphide (InAsP), indium gallium arsenide (InGaAs), gallium nitride (GaN), or indium gallium arsenide (InGaAsN).

(3)

The solid-state imaging device according to (1) or (2), in which

the recessed region is also formed below the photoelectric conversion regions and on a side of surface of the substrate, the surface facing the light receiving surface.

(4)

The solid-state imaging device according to any one of (1) to (3), in which

a back-surface antireflective film, a low refractive index material, and a high refractive index material are stacked in the trench.

(5)

A solid-state imaging device including:

a substrate;

a plurality of photoelectric conversion regions formed in the substrate;

a trench that is formed between the photoelectric conversion regions, and penetrates the substrate;

a recessed region that includes a plurality of concave portions, and is provided above the photoelectric conversion regions and on a side of a light receiving surface of the substrate; and

a metal film that is provided below the photoelectric conversion regions and on a side of a surface of the substrate, the surface facing the light receiving surface.

(6)

The solid-state imaging device according to (5), further including

a storage portion that stores electric charge converted in the photoelectric conversion regions.

(7)

The solid-state imaging device according to (5) or (6), in which

the recessed region is also formed between the photoelectric conversion regions and the metal film.

(8)

A solid-state imaging device including:

a substrate;

a plurality of photoelectric conversion regions formed in the substrate;

a color filter that is provided on an upper side of the photoelectric conversion regions;

a trench that is formed between the photoelectric conversion regions, and penetrates the substrate;

a recessed region that includes a plurality of concave portions, and is provided above the photoelectric conversion regions and on a side of a light receiving surface of the substrate; and

a film that is provided above the trench, and has materials having different refractive indexes stacked on the color filter.

(9)

The solid-state imaging device according to (8), in which

the film is also stacked on the recessed region, and the film stacked on the recessed region has a flat shape.

(10)

A solid-state imaging device including:

a substrate;

a plurality of photoelectric conversion regions formed in the substrate;

a color filter that is provided on an upper side of the photoelectric conversion regions;

a trench that is formed between the photoelectric conversion regions, and penetrates the substrate; and

a recessed region that includes a plurality of concave portions, and is provided above the photoelectric conversion regions and on a side of a light receiving surface of the substrate,

in which the color filter has a flat shape on a side of the recessed region.

(11)

The solid-state imaging device according to (10), further including

a metal film between the trench and the color filter.

(12)

A solid-state imaging device including:

a substrate;

a plurality of photoelectric conversion regions formed in the substrate;

a trench that is formed between the photoelectric conversion regions, and penetrates the substrate; and

a recessed region that includes a plurality of concave portions, and is provided above the photoelectric conversion regions and on a side of a light receiving surface of the substrate,

in which

a color filter, and a dual pass filter that has transmission bands for visible light and near-infrared light in a predetermined range are stacked on the photoelectric conversion regions for visible light, and

different color filters are stacked on the photoelectric conversion regions for infrared light.

(13)

The solid-state imaging device according to (12), in which

the different color filters include a red filter and a blue filter.

(14)

The solid-state imaging device according to (12) or (13), in which

the number of the concave portions in the recessed region provided above the photoelectric conversion regions for visible light is different from the number of the concave portions in the recessed region provided above the photoelectric conversion regions for infrared light.

(15)

The solid-state imaging device according to any one of (12) to (14), in which

the number of the concave portions in the recessed region provided above the photoelectric conversion regions for visible light varies with each color.

### REFERENCE SIGNS LIST

1 Solid-state imaging device
2 Pixel
3 Pixel array unit
4 Vertical drive circuit
5 Column signal processing circuit
6 Horizontal drive circuit
7 Output circuit
8 Control circuit
9 Vertical signal line
10 Pixel drive line
11 Horizontal signal line
12 Semiconductor substrate
13 Input/output terminal
41 Semiconductor region
42 Semiconductor region
46 Transparent insulating film
48 Recessed region
49 Light blocking film
51 Color filter layer
52 On-chip lens
53 Flat portion
54 Pixel separation portion
55 Insulator
56 Light shield
61 Antireflective film
62 Hafnium oxide film
63 Aluminum oxide film
64 Silicon oxide film
101 Reflective film
102 Transfer gate
103 Transistor
104 Transistor
112 Transfer gate
113 Reset gate
114 Amplification transistor
115 Wiring line
117 Charge retaining portion
150 Waveguide
151 Film
152 Film
171 Planarizing material
201 Dual pass filter
202 IR filter
211 R filter
212 B filter

1. A solid-state imaging device comprising:
a substrate;
a plurality of photoelectric conversion regions formed in the substrate;
a trench that is formed between the photoelectric conversion regions, and penetrates the substrate; and
a recessed region that includes a plurality of concave portions, and is provided above the photoelectric conversion regions and on a side of a light receiving surface of the substrate,
wherein the substrate includes a III-V semiconductor or polycrystalline SiXGe (1-x) (x=0 to 1).

2. The solid-state imaging device according to claim 1, wherein
the III-V semiconductor includes one of indium phosphide (InP), indium arsenide (InAs), indium arsenide phosphide (InAsP), indium gallium arsenide (InGaAs), gallium nitride (GaN), or indium gallium arsenide (InGaAsN).

3. The solid-state imaging device according to claim 1, wherein
the recessed region is also formed below the photoelectric conversion regions and on a side of a surface of the substrate, the surface facing the light receiving surface.

4. The solid-state imaging device according to claim 1, wherein
a back-surface antireflective film, a low refractive index material, and a high refractive index material are stacked in the trench.

5. A solid-state imaging device comprising:
a substrate;
a plurality of photoelectric conversion regions formed in the substrate;
a trench that is formed between the photoelectric conversion regions, and penetrates the substrate;
a recessed region that includes a plurality of concave portions, and is provided above the photoelectric conversion regions and on a side of a light receiving surface of the substrate; and
a metal film that is provided below the photoelectric conversion regions and on a side of a surface of the substrate, the surface facing the light receiving surface.

6. The solid-state imaging device according to claim 5, further comprising
a storage portion that stores electric charge converted in the photoelectric conversion regions.

7. The solid-state imaging device according to claim 5, wherein
the recessed region is also formed between the photoelectric conversion regions and the metal film.

8. A solid-state imaging device comprising:
a substrate;
a plurality of photoelectric conversion regions formed in the substrate;
a color filter that is provided on an upper side of the photoelectric conversion regions;
a trench that is formed between the photoelectric conversion regions, and penetrates the substrate;
a recessed region that includes a plurality of concave portions, and is provided above the photoelectric conversion regions and on a side of a light receiving surface of the substrate; and
a film that is provided above the trench, and has materials having different refractive indexes stacked on the color filter.

9. The solid-state imaging device according to claim 8, wherein
the film is also stacked on the recessed region, and the film stacked on the recessed region has a flat shape.

10. A solid-state imaging device comprising:
a substrate;
a plurality of photoelectric conversion regions formed in the substrate;
a color filter that is provided on an upper side of the photoelectric conversion regions;
a trench that is formed between the photoelectric conversion regions, and penetrates the substrate; and
a recessed region that includes a plurality of concave portions, and is provided above the photoelectric conversion regions and on a side of a light receiving surface of the substrate,
wherein the color filter has a flat shape on a side of the recessed region.

11. The solid-state imaging device according to claim 10, further comprising
a metal film between the trench and the color filter.

12. A solid-state imaging device comprising:
a substrate;
a plurality of photoelectric conversion regions formed in the substrate;
a trench that is formed between the photoelectric conversion regions, and penetrates the substrate; and
a recessed region that includes a plurality of concave portions, and is provided above the photoelectric conversion regions and on a side of a light receiving surface of the substrate,
wherein
a color filter, and a dual pass filter that has transmission bands for visible light and near-infrared light in a predetermined range are stacked on the photoelectric conversion regions for visible light, and
different color filters are stacked on the photoelectric conversion regions for infrared light.

13. The solid-state imaging device according to claim 12, wherein
the different color filters include a red filter and a blue filter.

14. The solid-state imaging device according to claim 12, wherein
the number of the concave portions in the recessed region provided above the photoelectric conversion regions for visible light is different from the number of the concave portions in the recessed region provided above the photoelectric conversion regions for infrared light.

15. The solid-state imaging device according to claim 12, wherein
the number of the concave portions in the recessed region provided above the photoelectric conversion regions for visible light varies with each color.
